(19) United States
(12) Patent Application Publication
(10) Pub. No.: US 2026/0149428 A1
(43) Pub. Date: May 28, 2026

(54) ACOUSTIC WAVE DEVICE, FILTER, AND MULTIPLEXER

(71) Applicant: TAIYO YUDEN CO., LTD., Tokyo (JP)

(72) Inventors: Satoshi IMASU, Tokyo (JP); Ryohei KOMIYAMA, Tokyo (JP); Koichi SATO, Tokyo (JP); Ryusuke UMEDA, Tokyo (JP); Kaoru SAKINADA, Tokyo (JP)

(73) Assignee: TAIYO YUDEN CO., LTD., Tokyo (JP)

(21) Appl. No.: 19/368,263

(22) Filed: Oct. 24, 2025

(30) Foreign Application Priority Data
Nov. 25, 2024 (JP) 2024-204870
Jun. 27, 2025 (JP) 2025-109244
Jun. 27, 2025 (JP) 2025-109245
Jul. 25, 2025 (JP) 2025-124949

(51) Int. Cl. H03H 9/02; H03H 9/145; H03H 9/64

(52) U.S. Cl. CPC H03H 9/02929; H03H 9/02834; H03H 9/14541; H03H 9/6483

(57) ABSTRACT

An acoustic wave device includes a piezoelectric layer and a pair of interdigital electrodes including electrode fingers. Each of the electrode fingers includes a first layer provided on the piezoelectric layer and having an electrical resistivity of more than 1272 Ω·nm and 25038 Ω·nm or less, and a second layer provided on the first layer and having an electrical resistivity smaller than that of the first layer.

### CROSS-REFERENCE TO RELATED APPLICATION

This application claims priority based on Japanese Patent Applications No. 2024-204870 filed on Nov. 25, 2024, No. 2025-109244 filed on Jun. 27, 2025, No. 2025-109245 filed on Jun. 27, 2025, and No. 2025-124949 filed on Jul. 25, 2025, and the entire contents of the Japanese patent applications are incorporated herein by reference.

### FIELD

A certain aspect of the present invention relates to an acoustic wave device, a filter, and a multiplexer.

### BACKGROUND

In a high-frequency communication system represented by a mobile phone, a high-frequency filter is used to remove unnecessary signals other than a frequency band used for communication. For example, a surface acoustic wave (SAW) resonator is used for the high-frequency filter. In the surface acoustic wave resonator, an interdigital transducer (IDT) including a plurality of electrode fingers is provided on a piezoelectric layer such as a lithium tantalate layer or a lithium niobate layer. It is known to use an aluminum layer or an aluminum alloy layer as the electrode finger (for example, Japanese Patent Application Publication No. 2015-89069, and Japanese Patent Application Publication No. 2008-244523). In addition, it is known that a titanium aluminum nitride layer is used for a buffer layer in a capacitor in which the buffer layer, a dielectric layer, and an electrode are stacked (for example, Japanese Patent Application Publication No. 2015-8509).

In order to improve the electric power durability, it is known to use an electrode finger in which a titanium layer or a titanium-alloy layer having a thickness larger than the thickness of 10 nm, a barrier layer such as a titanium nitride layer or an aluminum nitride layer, and an aluminum layer or an aluminum-alloy layer are sequentially stacked (for example, Japanese Patent Application Publication No. 2023-64367). In order to improve the temperature characteristics, it is also known to use an electrode finger in which a titanium nitride layer having a thickness larger than the thickness of 50 nm and an aluminum layer, an aluminum alloy layer, a copper layer, or a copper alloy layer are stacked (for example, Japanese Patent Application Publication No. 2024-72778). A configuration in which insulating films separated from each other are provided between the piezoelectric layer and the plurality of respective electrode fingers is also known (for example, Japanese Patent Application Publication No. 2008-78739).

### SUMMARY OF THE INVENTION

According to a first aspect of the present disclosure, there is provided an acoustic wave device including: a piezoelectric layer; and a pair of interdigital electrodes including electrode fingers, each of the electrode fingers including a first layer provided on the piezoelectric layer and having an electrical resistivity of more than 1272 Ω·nm and 25038 Ω·nm or less, and a second layer provided on the first layer and having an electrical resistivity smaller than that of the first layer.

According to a second aspect of the present disclosure, there is provided an acoustic wave device including: a piezoelectric layer; and a pair of interdigital electrodes including electrode fingers, each of the electrode fingers having a first layer provided on the piezoelectric layer and being a titanium aluminum nitride layer, a chromium aluminum nitride layer, a chromium nitride layer, a diamond-like carbon layer, or a titanium carbonitride layer, and a second layer provided on the first layer and being a metal layer formed of a metal having an electrical resistivity smaller than that of the first layer.

According to a third aspect of the present disclosure, there is provided an acoustic wave device including: a piezoelectric layer having a surface with an arithmetic average roughness Ra of 0.60 nm or less, and a pair of interdigital electrodes including electrode fingers, each of the electrode fingers including a first layer provided on the piezoelectric layer and a second layer provided on the first layer, the second layer having a thickness equal to or greater than a thickness of the first layer and being an aluminum layer or an aluminum alloy layer having an electric resistivity smaller than that of the first layer.

### BRIEF DESCRIPTION OF THE DRAWINGS

FIG. 1A is a plan view of an acoustic wave device in accordance with a first embodiment.

FIG. 1B is a cross-sectional view of electrode fingers in the first embodiment.

FIGS. 2A to 2D are cross-sectional views of acoustic wave resonators of samples A to D used in an experiment.

FIG. 3 is a diagram illustrating results of an electric power durability test of the acoustic wave resonators of samples A to D.

FIG. 4 is a diagram illustrating the measurement results of the temperature coefficient of frequency (TCF) of the anti-resonant frequency of the acoustic wave resonators of the samples A to D.

FIG. 5 is a cross-sectional view of an acoustic wave device in accordance with a first modification of the first embodiment.

FIGS. 6A to 6E are cross-sectional views of acoustic wave devices in accordance with second to sixth modifications of the first embodiment.

FIGS. 7A and 7B are cross-sectional views of acoustic wave devices in accordance with seventh and eighth modifications of the first embodiment.

FIG. 8 is a binary phase diagram of titanium aluminum.

FIG. 9A is a plan view of an acoustic wave device in accordance with a third embodiment.

FIG. 9B is a cross-sectional view of electrode fingers in the third embodiment.

FIG. 10 is a diagram illustrating the results of the pass characteristics of samples E, F, G, and H in Experiment 3.

FIG. 11 is a diagram illustrating the results of the electromechanical coupling coefficients of samples I, J, and K in Experiment 4.

FIGS. 12A and 12B are cross-sectional views of electrode fingers in a first modification and a second modification of the third embodiment.

FIGS. 13A to 13E are cross-sectional views of acoustic wave devices in accordance with third to seventh modifications of the third embodiment.

FIG. 14A is a plan view of an acoustic wave device in accordance with a fourth embodiment.

FIG. 14B is a cross-sectional view of electrode fingers in the fourth embodiment.

FIG. 15A is a cross-sectional view of samples L and M used in the experiment.

FIGS. 15B and 15C are schematic views illustrating the results of pole measurement of Al (111) orientation of an AlCu layer in the samples L and M.

FIGS. 16A to 16C are cross-sectional views of samples N to P used in the experiment.

FIGS. 17A to 17C are schematic diagrams illustrating the results of pole measurement of Al (111) orientation of the AlCu layer in the samples N to P.

FIGS. 18A and 18B are diagrams illustrating the measurement results of the crystallite size in the samples L to P.

FIG. 19A is a circuit diagram of a filter in accordance with a fifth embodiment.

FIG. 19B is a circuit diagram of a duplexer in accordance with a modification of the fifth embodiment.

### DETAILED DESCRIPTION

An electrode finger in which a first layer provided on a piezoelectric layer and a second layer provided on the first layer and having an electrical resistivity smaller than the electrical resistivity of the first layer are stacked may be used. The first layer is provided, for example, to improve adhesion to the piezoelectric layer and/or to improve the electric power durability. When electrode fingers having a large electrical resistance are used, the electromechanical coupling coefficient of the acoustic wave resonator is reduced, and the pass band width of the filter is narrowed. On the other hand, it is desirable that the choice of materials that can be used for the first layer is wide.

It is known that the electric power durability of the electrode finger can be improved by providing a titanium layer between the piezoelectric layer and a low-resistance metal layer such as aluminum. However, there is still room for improvement in terms of improving the electric power durability.

The present disclosure has been made in view of the above problems, and an object of the present disclosure is to widen the range of choices of materials that can be used for the first layer while suppressing a decrease in the electromechanical coupling coefficient. Alternatively, an object of the present disclosure is to improve the electric power durability.

Hereinafter, embodiments of the present invention will be described with reference to the drawings.

### First Embodiment

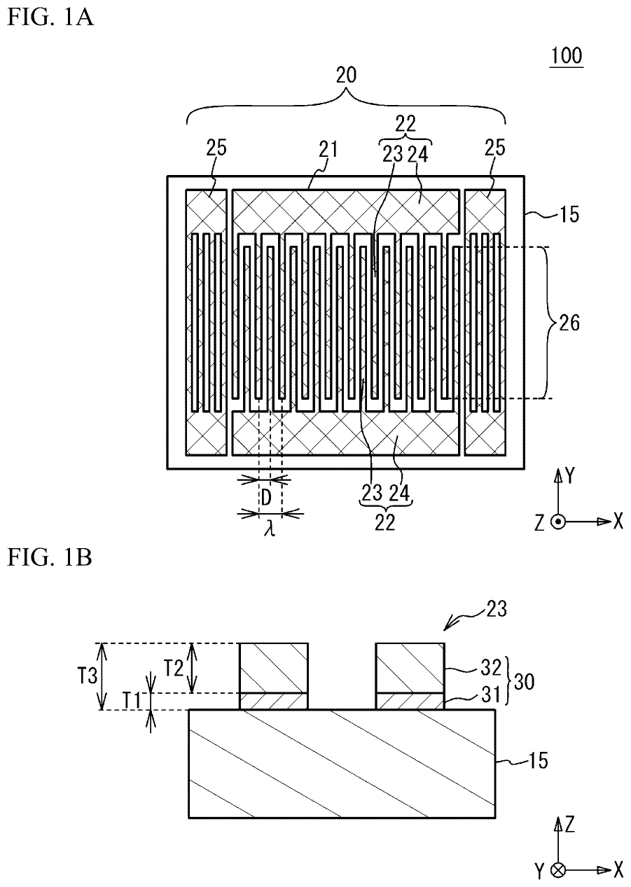

FIG. 1A is a plan view of an acoustic wave device 100 in accordance with a first embodiment, and FIG. 1B is a cross-sectional view of an electrode finger 23 in the first embodiment. The arrangement direction of the electrode fingers 23 is defined as an X direction, the extending direction of the electrode fingers 23 is defined as a Y direction, and the thickness direction of a piezoelectric layer 15 is defined as a Z direction. The X direction, the Y direction, and the Z direction do not necessarily correspond to an X-axis direction and a Y-axis direction of the crystal orientation of the piezoelectric layer 15. When the piezoelectric layer 15 is a rotated Y-cut X-propagation piezoelectric layer, the X direction is the X-axis direction of the crystal orientation.

As illustrated in FIG. 1A, an acoustic wave resonator 20 is located on the piezoelectric layer 15. In the first embodiment, the piezoelectric layer 15 is a piezoelectric substrate. The piezoelectric layer 15 is formed of, for example, single crystal lithium tantalate, single crystal lithium niobate, or quartz crystal. The piezoelectric layer 15 may be, for example, a rotated Y-cut X-propagation lithium tantalate layer or a rotated Y-cut X-propagation lithium niobate layer, for example, a 30° to 50° rotated Y-cut X-propagation lithium tantalate layer. The acoustic wave resonator 20 includes an interdigital transducer (IDT) 21 and reflectors 25. The reflectors 25 are provided on both sides of the IDT 21 in the X direction. The IDT 21 includes a pair of interdigital electrodes 22 facing each other. The interdigital electrode 22 includes a plurality of electrode fingers 23 and a bus bar 24 to which the plurality of electrode fingers 23 are connected. A region where the electrode fingers 23 of the pair of interdigital electrodes 22 intersect is an intersection region 26. The length of the intersection region 26 in the Y direction is an opening length.

In the pair of interdigital electrodes 22, the electrode fingers 23 are alternately provided one by one in at least a part of the intersection region 26. The acoustic wave excited mainly by the plurality of electrode fingers 23 in the intersection region 26 propagates mainly in the X direction. The pitch of the electrode fingers 23 of one of the pair of interdigital electrodes 22 is substantially a wavelength λ of the acoustic wave. The wavelength λ is substantially twice an average pitch D of the plurality of electrode fingers 23. The average pitch D can be calculated by dividing the length of the IDT 21 in the X direction by the number of electrode fingers 23. The reflectors 25 reflect the acoustic wave (surface acoustic wave) excited by the electrode fingers 23 of the IDT 21. Thus, the acoustic wave is confined in the intersection region 26 of the IDT 21.

As illustrated in FIG. 1B, the IDT 21 including the electrode finger 23 and the like, and the reflector 25 are formed by a conductive film 30 provided on the piezoelectric layer 15. The conductive film 30 includes a first layer 31 provided on the piezoelectric layer 15 and a second layer 32 provided in contact with the upper surface of the first layer 31. The thicknesses of the first layer 31 and the second layer 32 are denoted by T1 and T2, respectively. The thickness of the conductive film 30 is denoted by T3. Formation “T3=T1+T2” is satisfied.

The first layer 31 is a titanium aluminum nitride layer (TiAlN layer), has conductivity, and is polycrystalline or amorphous. The first layer 31 may include an intentional or unintentional impurity other than titanium (Ti), aluminum (Al), and nitrogen (N). In the first layer 31, for example, the proportion of aluminum atoms is 20 atomic % or more and 50 atomic % or less when the total of titanium atoms and aluminum atoms is 100 atomic %. In the first layer 31, for example, the proportion of nitrogen atoms is 10 atomic % or more and 60 atomic % or less when the total of titanium atoms, aluminum atoms, and nitrogen atoms is 100 atomic %. The atomic concentration can be measured by using, for example, secondary ion mass spectrometry, Auger electron spectroscopy, or the like. The thickness T1 of the first layer 31 varies depending on the band in which the acoustic wave device 100 is used, and is, for example, 120 nm or more and 300 nm or less when used in the low band (less than 1 GHZ), 30 nm or more and 90 nm or less when used in the middle band (equal to or greater than 1 GHz and equal to or less than 7 GHZ), and 5 nm or more and 60 nm or less when used in the high band (greater than 7 GHZ). The thickness T1 of the first layer 31 may be, for example, 5% or more and 60% or less of the thickness T3 of the electrode finger 23.

The second layer 32 is, for example, an aluminum layer (Al layer) or an aluminum alloy layer (Al alloy layer), and is, for example, polycrystalline or amorphous. When the second layer 32 is an aluminum alloy layer, the second layer 32 contains at least one element of copper (Cu), magnesium (Mg), scandium (Sc), zirconium (Zr), titanium (Ti), neodymium (Nd), and silicon (Si), in addition to aluminum (Al). When the second layer 32 is an aluminum layer, the second layer 32 may contain an intentional or unintentional impurity other than aluminum. When the second layer 32 is an aluminum alloy layer, the second layer 32 may contain an intentional or unintentional impurity in addition to aluminum and the metal elements constituting the aluminum alloy. The content of aluminum in the second layer 32 is, for example, 80 atomic % or more, and 90 atomic % or more. The thickness T2 of the second layer 32 may be greater than the thickness T1 of the first layer 31. The thickness T2 of the second layer 32 varies depending on the band in which the acoustic wave device 100 is used, and is, for example, 150 nm or more and 350 nm or less when used in the low band (less than 1 GHZ), 100 nm or more and 200 nm or less when used in the middle band (equal to or greater than 1 GHz and equal to or less than 7 GHZ), and 80 nm or more and 120 nm or less when used in the high band (greater than 7 GHZ). The thickness T2 of the second layer 32 may be, for example, 40% or more and 95% or less of the thickness T3 of the electrode finger 23.

### [Manufacturing Method]

The acoustic wave device 100 in accordance with the first embodiment is manufactured by the following method. First, the first layer 31, which is a TiAlN layer, is formed on the piezoelectric layer 15. For example, the first layer 31 is formed by a sputtering method using a titanium-aluminum (TiAl) target, argon (Ar) gas, and nitrogen gas (N₂). The nitrogen content can be adjusted by adjusting the flow volume of the N₂ gas. The content of Ti and Al can be adjusted by changing the ratio of Ti and Al in the TiAl alloy target.

Next, the second layer 32, which is an Al layer or an Al alloy layer, is formed on the first layer 31. For example, when the second layer 32 is the Al layer, the second layer 32 is formed by a sputtering method using an Al target and Ar gas. When the second layer 32 is the Al alloy layer, the second layer 32 is formed by a sputtering method using the Al alloy target in which another element is added to aluminum and Ar gas.

Next, the first layer 31 and the second layer 32 are formed into a desired shape by a photolithography method and an etching method, thereby forming the IDT 21 and the reflectors 25. As described above, the acoustic wave device 100 in accordance with the first embodiment is formed.

### Experiment 1

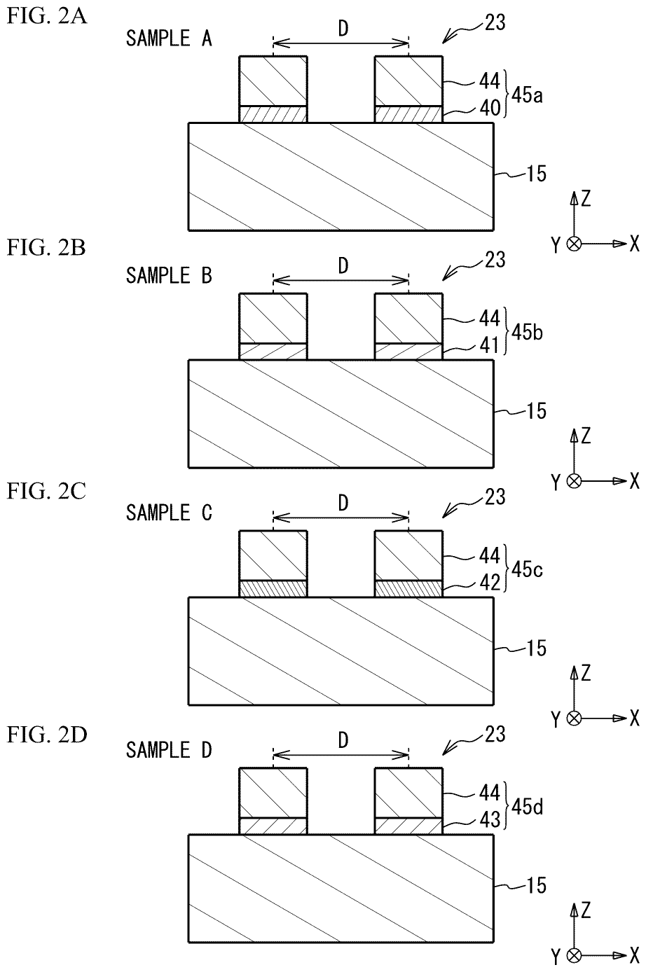

FIGS. 2A to 2D are cross-sectional views of acoustic wave resonators of samples A through D used in Experiment 1. In the samples A to D, a 42° rotated Y-cut X-propagation lithium tantalate layer was used as the piezoelectric layer 15. As illustrated in FIG. 2A, in the acoustic wave resonator of the sample A, the IDT 21 including the electrode finger 23 and the like, and the reflector 25 were formed of a conductive film 45a in which a titanium layer 40 and an aluminum-copper alloy layer 44 were stacked. The thickness of the titanium layer 40 was 60 nm, and the thickness of the aluminum-copper alloy layer 44 was 90 nm. The wavelength λ (2×D) of the acoustic wave was set to 1.5 μm.

As illustrated in FIG. 2B, in the acoustic wave resonator of the sample B, the IDT 21 including the electrode finger 23 and the like, and the reflector 25 are formed of a conductive film 45b in which a titanium-aluminum alloy layer 41 (TiAl-alloy layer) and the aluminum-copper alloy layer 44 are stacked. In the titanium-aluminum alloy layer 41, the proportion of aluminum atoms was 36 atomic % when the total of titanium atoms and aluminum atoms was 100 atomic %. The thickness of the titanium-aluminum alloy layer 41 was 60 nm, and the thickness of the aluminum-copper alloy layer 44 was 90 nm. The wavelength λ (2×D) of the acoustic wave was set to 1.5 μm.

As illustrated in FIG. 2C, in the acoustic wave resonator of the sample C, the IDT 21 including the electrode finger 23 and the like, and the reflector 25 were formed of a conductive film 45c in which a titanium nitride layer 42 and the aluminum-copper alloy layer 44 were stacked. The thickness of the titanium nitride layer 42 was 60 nm, and the thickness of the aluminum-copper alloy layer 44 was 90 nm. The wavelength λ (2×D) of the acoustic wave was set to 1.5 μm.

As illustrated in FIG. 2D, in the acoustic wave resonator of the sample D, the IDT 21 including the electrode finger 23 and the like, and the reflector 25 were formed of a conductive film 45d in which a titanium aluminum nitride layer 43 (TiAlN layer) and the aluminum-copper alloy layer 44 were stacked. In the titanium aluminum nitride layer 43, the proportion of aluminum atoms was 36 atomic % when the total of titanium atoms and aluminum atoms was 100 atomic %. The proportion of nitrogen atoms was 50 atomic % when the total of titanium atoms, aluminum atoms, and nitrogen atoms was 100 atomic %. The thickness of the titanium aluminum nitride layer 43 was 60 nm, and the thickness of the aluminum-copper alloy layer 44 was 90 nm. The wavelength λ (2×D) of the acoustic wave was set to 1.5 μm.

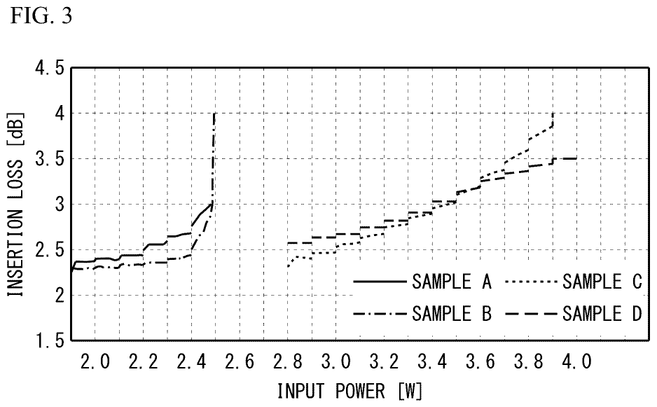

An electric power durability test was performed on the acoustic wave resonators of samples A to D. The electric power durability test employed a step stress accelerated life test (SSALT) in which the applied power was increased stepwise. FIG. 3 is a diagram illustrating the results of the electric power durability test of the acoustic wave resonators of the samples A to D. In FIG. 3, a horizontal axis represents an input power input to the acoustic wave resonator, and a vertical axis represents an insertion loss. As illustrated in FIG. 3, the insertion loss of the samples A and B significantly deteriorated at a stage where the input power was relatively small. On the other hand, although the deterioration of the insertion loss was suppressed in both the sample C and the sample D even when the input power was increased, the deterioration of the insertion loss was further suppressed in the sample D than in the sample C.

When the surfaces of the samples A to D after the electric power durability test were observed, the occurrence of electromigration was suppressed in the sample D as compared with the samples A to C. From this, it is considered that the deterioration of the insertion loss was suppressed in the sample D because the occurrence of the electromigration was suppressed and the electric power durability was improved.

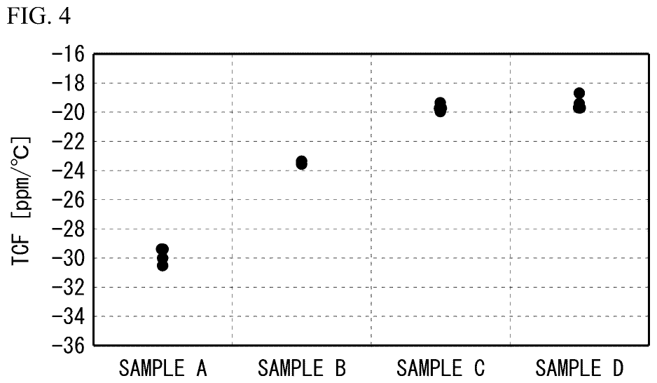

Next, the temperature coefficient of frequency (TCF) of the anti-resonant frequency of the acoustic wave resonators of the samples A to D was measured when the environmental temperature was changed from 25° C. to 85° C. FIG. 4 is a graph illustrating measurement results of TCFs at anti-resonant frequencies of the acoustic wave resonators of the samples A to D. As illustrated in FIG. 4, the absolute value of the TCF of the sample D was smaller than those of the samples A to C.

The reason why the sample D has improved power durability and TCF as compared with the samples A to C is not clear, but the following is considered, for example. Table 1 illustrates the results of measurement of a resistance value, a density, and a Young's modulus of each of a Ti layer (titanium layer), a TiAl alloy layer (titanium aluminum alloy layer), a TiN layer (titanium nitride layer), and a TiAlN layer (titanium aluminum nitride layer) formed on a silicon substrate. An acoustic velocity is a value calculated using the density and the Young's modulus. The TiAl alloy layer is a measurement value when the proportion of aluminum atoms is 36 atomic % when the total of titanium atoms and aluminum atoms is 100 atomic %. The TiAlN layer is a measurement value when the proportion of aluminum atoms is 36 atomic % when the total of titanium atoms and aluminum atoms is 100 atomic %, and the proportion of nitrogen atoms is 50 atomic % when the total of titanium atoms, aluminum atoms, and nitrogen atoms is 100 atomic %.

TABLE 1

| | | TiAl | | |
|---|---|---|---|---|
| | Ti layer | alloy layer | TiN layer | TiAlN layer |
| Resistance | 602 | 2079.1 | 1272 | 25037.9 |
| value[Ω · nm] | | | | |
| Density[g/cm³] | 4.53 | 3.88 | 5.02 | 4.52 |
| Young's | 155 | 179 | 311 | 325 |
| modulus[Gpa] | | | | |
| Acoustic | 3628 | 4210 | 4877 | 5260 |
| velocity[m/s] | | | | |

As illustrated in Table 1, the Young's modulus of the TiAlN layer is larger than the Young's modulus of the Ti layer, the TiAl alloy layer, and the TiN layer. Since the electrode finger 23 of the sample D uses the titanium aluminum nitride layer 43 (TiAlN layer), the large Young's modulus of the titanium aluminum nitride layer 43 is considered to be one of the reasons why the electric power durability is improved and the TCF is improved. That is, it is considered that the titanium aluminum nitride layer 43 having a large Young's modulus is provided as a base film of the aluminum copper alloy layer 44, and thus, the aluminum copper alloy layer 44 is not easily deformed even when the electrode finger 23 is excited. Thus, in the sample D, it is considered that the distortion generated in the aluminum-copper alloy layer 44 is reduced, the electromigration is suppressed, and the electric power durability is improved. In addition, the Young's modulus of the material constituting the electrode fingers 23 changes with temperature, and is larger than the change in the Young's modulus of the piezoelectric layer 15 with temperature. It is considered that the TCF was improved because the titanium aluminum nitride layer 43 had a large Young's modulus and was therefore less likely to be deformed even when the Young's modulus of the titanium aluminum nitride layer 43 and the aluminum-copper alloy layer 44 changed with temperature. Further, as illustrated in Table 1, the TiAlN layer has a high Young's modulus, and thus the acoustic velocity is high. It is considered that when the titanium aluminum nitride layer 43 having a high acoustic velocity is provided as a base film of the aluminum-copper alloy layer 44, a large amount of acoustic wave energy is distributed in the piezoelectric layer 15. This is also considered to be the reason why the TCF of the sample D is improved.

Based on the above experimental results, it can be seen that in the first embodiment, the electrode finger 23 is formed of the conductive film 30 in which the first layer 31 that is a titanium aluminum nitride layer and the second layer 32 that is an aluminum layer or an aluminum alloy layer are stacked, and thus the effects of improving the electric power durability and improving the TCF are obtained.

### Modifications

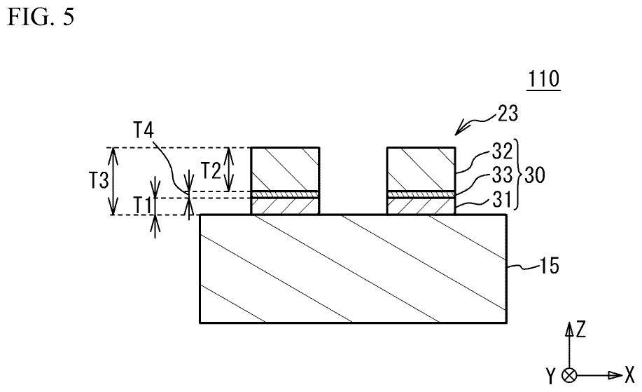

FIG. 5 is a cross-sectional view of an acoustic wave device 110 in accordance with a first modification of the first embodiment. As illustrated in FIG. 5, in the first modification of the first embodiment, a third layer 33 that is a titanium layer or a titanium nitride layer is provided between the first layer 31 and the second layer 32. A thickness T4 of the third layer 33 is smaller than the thickness T1 of the first layer 31 and the thickness T2 of the second layer 32. When the third layer 33 is provided, the thickness T3 of the electrode finger 23 is “T3=T1+T2+T4”. The other configurations of the first modification of the first embodiment are the same as those of the first embodiment, and thus the description thereof will be omitted.

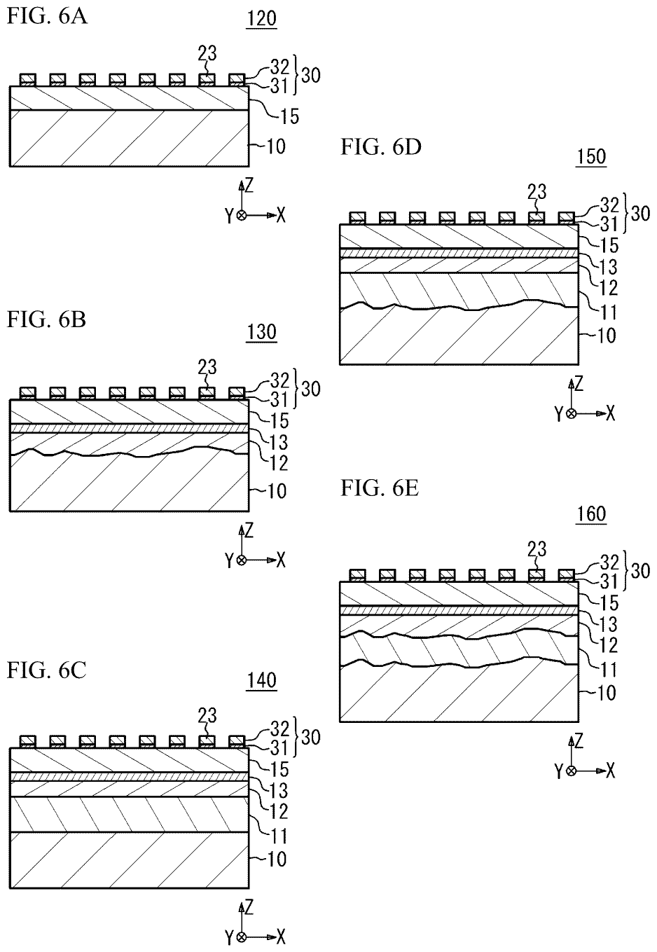

FIG. 6A is a cross-sectional view of an acoustic wave device 120 in accordance with a second modification of the first embodiment. As illustrated in FIG. 6A, in the second modification of the first embodiment, the piezoelectric layer 15 is provided on a substrate 10. The other configurations of the second modification of the first embodiment are the same as those of the first embodiment, and thus the description thereof will be omitted.

FIG. 6B is a cross-sectional view of an acoustic wave device 130 in accordance with a third modification of the first embodiment. As illustrated in FIG. 6B, in the third modification of the first embodiment, the piezoelectric layer 15 is provided on the substrate 10. An insulating layer 12 is provided between the substrate 10 and the piezoelectric layer 15. An insulating layer 13 is provided between the insulating layer 12 and the piezoelectric layer 15. An interface between the substrate 10 and the insulating layer 12 is rough. The other configurations of the third modification of the first embodiment are the same as those of the first embodiment, and thus the description thereof will be omitted.

FIG. 6C is a cross-sectional view of an acoustic wave device 140 in accordance with a fourth modification of the first embodiment. As illustrated in FIG. 6C, in the fourth modification of the first embodiment, the piezoelectric layer 15 is provided on the substrate 10. An insulating layer 11 is provided between the substrate 10 and the piezoelectric layer 15. The insulating layer 12 is provided between the insulating layer 11 and the piezoelectric layer 15. The insulating layer 13 is provided between the insulating layer 12 and the piezoelectric layer 15. The other configurations of the fourth modification of the first embodiment are the same as those of the first embodiment, and thus the description thereof will be omitted.

FIG. 6D is a cross-sectional view of an acoustic wave device 150 in accordance with a fifth modification of the first embodiment. In the fourth modification of the first embodiment, an interface between the substrate 10 and the insulating layer 11 is a mirror surface as illustrated in FIG. 6C, whereas in the fifth modification of the first embodiment, the interface between the substrate 10 and the insulating layer 11 is a rough surface as illustrated in FIG. 6D. The other configurations of the fifth modification of the first embodiment are the same as those of the fourth modification of the first embodiment, and thus the description thereof is omitted. An arithmetic average roughness Ra of the rough surface is, for example, larger than 10 nm and equal to or smaller than 100 nm, and the arithmetic average roughness Ra of the mirror surface is, for example, equal to or smaller than 10 nm and is about 1 nm.

FIG. 6E is a cross-sectional view of an acoustic wave device 160 in accordance with a sixth modification of the first embodiment. In the fourth and the fifth modifications of the first embodiment, the interface between the insulating layer 11 and the insulating layer 12 is the mirror surface as illustrated in FIGS. 6C and 6D, whereas in the sixth modification of the first embodiment, the interface between the insulating layer 11 and the insulating layer 12 is a rough surface as illustrated in FIG. 6E. The other configurations of the sixth modification of the first embodiment are the same as those of the fifth modification of the first embodiment, and thus the description thereof is omitted.

In the second to the sixth modifications of the first embodiment, the substrate 10 is, for example, a sapphire substrate, an alumina substrate, a silicon substrate, a spinel substrate, a quartz substrate, a quartz substrate, or a silicon carbide substrate. The acoustic velocity of a bulk wave propagating through the substrate 10 may be higher or lower than the acoustic velocity of a bulk wave propagating through the piezoelectric layer 15 and the insulating layers 11 to 13.

In the fourth to the sixth modifications of the first embodiment, the acoustic velocity of the bulk wave propagating through the insulating layer 11 is higher than the acoustic velocity of the bulk wave propagating through the insulating layer 12 and the piezoelectric layer 15. Accordingly, the energy of the acoustic wave of the main response is confined in the piezoelectric layer 15 and the insulating layer 12. The insulating layer 11 is, for example, polycrystalline or amorphous, and is an aluminum oxide layer, a silicon nitride layer, an aluminum nitride layer, a silicon layer, or a silicon carbide layer.

In the third to the sixth modifications of the first embodiment, the insulating layer 12 is a temperature compensation layer and has a temperature coefficient of an elastic constant with a sign opposite to that of the temperature coefficient of the elastic constant of the piezoelectric layer 15. For example, the temperature coefficient of the elastic constant of the piezoelectric layer 15 is negative, and the temperature coefficient of the elastic constant of the insulating layer 12 is positive. The insulating layer 12 is an insulating layer containing silicon oxide as a main component, and is, for example, a silicon oxide layer containing no additive or containing an additive element such as fluorine, and is, for example, polycrystalline or amorphous. This configuration reduces the temperature coefficient of frequency of the acoustic wave resonator. When the insulating layer 12 is a silicon oxide layer, the acoustic velocity of the bulk wave propagating through the insulating layer 12 is lower than the acoustic velocity of the bulk wave propagating through the piezoelectric layer 15.

The insulating layer 13 is a bonding layer and bonds the insulating layer 12 and the piezoelectric layer 15. When the insulating layer 12 is a silicon oxide layer, it is difficult to directly bond the piezoelectric layer 15 and the insulating layer 12 using a surface activation method. In such a case, an insulating layer made of a material different from that of the insulating layer 12 is provided as the insulating layer 13. The insulating layer 13 is, for example, polycrystalline or amorphous, and is an aluminum oxide layer, a silicon nitride layer, an aluminum nitride layer, a silicon layer, or a silicon carbide layer.

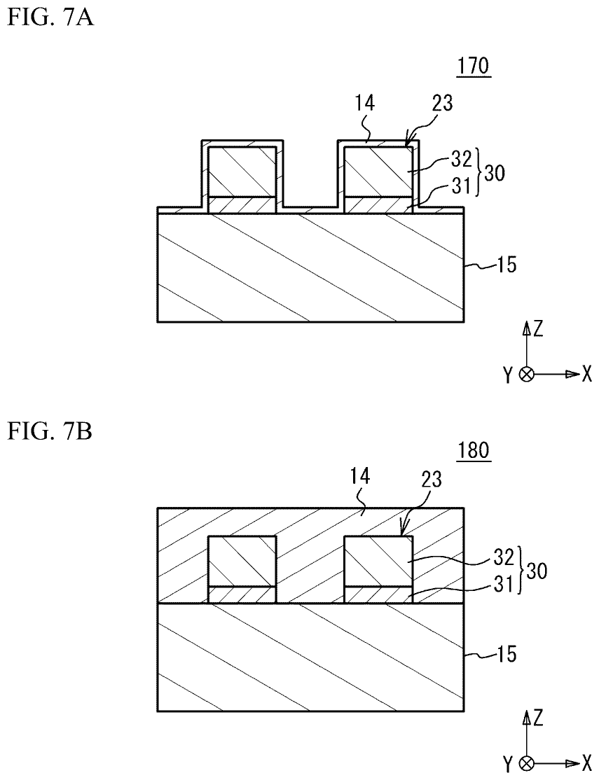

FIG. 7A is a cross-sectional view of an acoustic wave device 170 in accordance with a seventh modification of the first embodiment. As illustrated in FIG. 7A, in the seventh modification of the first embodiment, a protective film 14 is provided on the piezoelectric layer 15 to cover the electrode fingers 23. The thickness of the protective film 14 is smaller than the thickness of the electrode finger 23. The other configurations of the seventh modification of the first embodiment are the same as those of the first embodiment, and thus the description thereof will be omitted.

FIG. 7B is a cross-sectional view of an acoustic wave device 180 in accordance with an eighth modification of the first embodiment. As illustrated in FIG. 7B, in the eighth modification of the first embodiment, the protective film 14 is provided on the piezoelectric layer 15 to cover the electrode fingers 23. The thickness of the protective film 14 is larger than the thickness of the electrode finger 23, and the upper surface of the protective film 14 is flattened. The other configurations of the eighth modification of the first embodiment are the same as those of the first embodiment, and thus the description thereof will be omitted.

In the seventh and the eighth modifications of the first embodiment, the protective film 14 is an inorganic insulator film such as a silicon oxide film or a silicon nitride film.

In the first embodiment and the modifications thereof, the electrode finger 23 includes the first layer 31 provided on the piezoelectric layer 15 and the second layer 32 provided on the first layer 31. The first layer 31 is a titanium aluminum nitride layer (TiAlN layer). The second layer 32 is a metal layer formed of a metal having a lower electrical resistivity than the first layer 31, and is, for example, an aluminum layer or an aluminum alloy layer. As described above, since the first layer 31, which is a TiAlN layer, is provided between the piezoelectric layer 15 and the second layer 32, the electric power durability can be improved and the TCF can be improved as described with reference to FIGS. 3 and 4 because TiAlN has a large Young's modulus as illustrated in Table 1. Further, TiAlN has a low density despite its high Young's modulus as illustrated in Table 1. Therefore, even when the thickness T1 of the first layer 31 varies due to manufacturing errors or the like, the resonant frequency and the anti-resonant frequency can be suppressed from deviating from desired values. Further, TiAlN has conductivity despite its high Young's modulus and low density as illustrated in Table 1. Therefore, the electrode fingers 23 can be formed only of a conductive material, and thus, deterioration of characteristics can be suppressed.

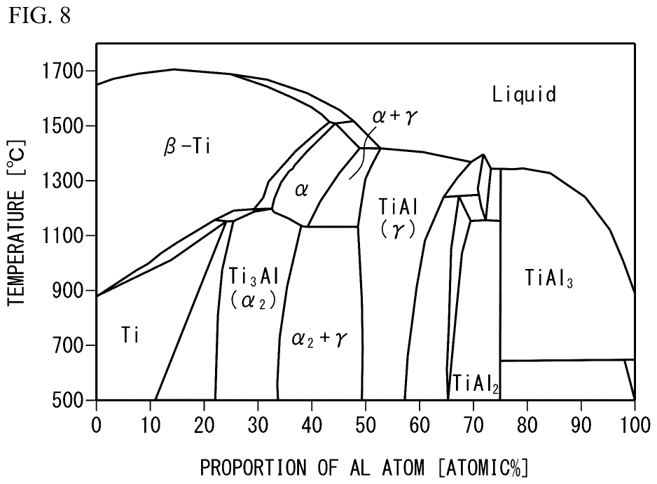

In the first embodiment and the modifications thereof, the first layer 31, which is a TiAlN layer, has a proportion of aluminum atoms of 20 atomic % or more and 50 atomic % or less when the total of titanium atoms and aluminum atoms is 100 atomic %. FIG. 8 is a two element phase diagram of titanium aluminum. In FIG. 8, a horizontal axis represents the proportion of aluminum atoms, and a vertical axis represents the temperature. As illustrated in FIG. 8, when the proportion of aluminum atoms is set to 20 atomic % or more and 50 atomic % or less, the titanium-aluminum alloy includes a Ti₃Al (α2) phase. The Ti₃Al (α2) phase has excellent heat resistance. Therefore, in the first layer 31, the proportion of the aluminum atoms is preferably 20 atomic % or more and 50 atomic % or less when the total of the titanium atoms and the aluminum atoms is 100 atomic %. From the viewpoint of obtaining the first layer 31 having excellent heat resistance and high-temperature strength, the titanium-aluminum alloy preferably includes a Ti₃Al (α2) phase and a TiAl (γ) phase. Therefore, the proportion of aluminum atoms is preferably 33 atomic % or more and 49 atomic % or less, more preferably 34 atomic % or more and 48 atomic % or less, and still more preferably 35 atomic % or more and 47 atomic % or less.

In the first embodiment and the modifications thereof, the first layer 31, which is a TiAlN layer, has a nitrogen atom content of 10 atomic % or more when the total of the titanium atoms, the aluminum atoms, and the nitrogen atoms is 100 atomic %. Thereby, the Young's modulus of the first layer 31 is large. Therefore, the electric power durability and the TCF can be improved. From the viewpoint of increasing the Young's modulus, the proportion of nitrogen atoms is preferably 15 atomic % or more, more preferably 20 atomic % or more, and still more preferably 30 atomic % or more. When the proportion of nitrogen atoms is increased, an increase in electric resistance and the like are considered, and therefore, the proportion of nitrogen atoms is preferably 60 atomic % or less, more preferably 55 atomic % or less, and still more preferably 50 atomic % or less.

In the first embodiment and the modifications thereof, the second layer 32 is an aluminum layer or an aluminum alloy layer. This reduces the electrical resistance of the electrode fingers 23. As described above, the second layer 32 may be formed of a metal having a lower electrical resistivity than the first layer 31 in order to function as a low resistance layer. The second layer 32 may be a copper layer or a copper alloy layer other than the aluminum layer or the aluminum alloy layer. When the second layer 32 is the copper layer, the second layer 32 may contain an intentional or unintentional impurity other than copper. When the second layer 32 is the copper alloy layer, the second layer 32 may contain an intentional or unintentional impurity other than copper and the metal elements constituting the copper alloy. The content of copper in the second layer 32 is, for example, 80 atomic % or more, and 90 atomic % or more.

In the first embodiment and the modifications thereof, the thickness T1 of the first layer 31 is 5% or more and 60% or less of the thickness T3 of the electrode finger 23. By setting the thickness T1 of the first layer 31 to such a size, the electric power durability and the TCF can be improved, and the thickness T2 of the second layer 32 is suppressed from being reduced. From the viewpoint of improving the electric power durability and the TCF, the thickness T1 of the first layer 31 is preferably equal to or greater than 10%, more preferably equal to or greater than 15%, and still more preferably equal to or greater than 20% of the thickness T3 of the electrode finger 23. In order to significantly reduce or suppress an increase in the electric resistance of the electrode finger 23, the thickness T1 of the first layer 31 is preferably equal to or less than 55%, more preferably equal to or less than 50%, and still more preferably equal to or less than 45% of the thickness T3 of the electrode finger 23.

In the first modification of the first embodiment, as illustrated in FIG. 5, the electrode finger 23 includes the third layer 33, which is a titanium layer or a titanium nitride layer and is thinner than the first layer 31 and the second layer 32, between the first layer 31 and the second layer 32. By providing the third layer 33 that is the titanium layer or the titanium nitride layer between the first layer 31 and the second layer 32, the adhesion between the first layer 31 and the second layer 32 can be improved. In addition, when the second layer 32 is an aluminum layer, an aluminum alloy layer, a copper layer, or a copper alloy layer, the third layer 33 is thinner than the first layer 31 and the second layer 32, and thus it is possible to suppress an increase in the electrical resistance of the electrode finger 23.

### Second Embodiment

While the first embodiment illustrates an example in which the first layer 31 is the titanium aluminum nitride layer, the second embodiment illustrates an example in which the first layer 31 is a chromium aluminum nitride layer, a chromium nitride layer, a diamond-like carbon layer, or a titanium carbonitride layer. The other configurations of the acoustic wave device in accordance with the second embodiment are the same as those of the first embodiment or the modifications thereof, and the description thereof is omitted.

Here, a CrAlN layer (chromium aluminum nitride layer), a CrN layer (chromium nitride layer), a DLC layer (diamond-like carbon layer), and a TiCN layer (titanium carbonitride layer) are formed on the silicon substrate, and the results of measuring the resistance value and the density of each film are illustrated. The Young's modulus is a literature value, and the acoustic velocity is a value calculated using the density and the Young's modulus. In the CrAlN layer, the proportion of aluminum atoms is 50 to 70 atomic % when the total of chromium atoms and aluminum atoms is 100 atomic %, and the proportion of nitrogen atoms is 50 atomic % when the total of chromium atoms, aluminum atoms, and nitrogen atoms is 100 atomic %. The CrN layer is a measurement value when the proportion of nitrogen atoms is 50 atomic % when the total of chromium atoms and nitrogen atoms is 100 atomic %. The TiCN layer is a measurement value when the proportion of titanium atoms is 50 atomic % and the proportion of carbon atoms to the total of carbon atoms and nitrogen atoms (carbon atoms/(carbon atoms+nitrogen atoms)) is 50% when the total of titanium atoms, carbon atoms, and nitrogen atoms is 100 atomic %.

### CrAlN Layer

Resistance value: 2. 8 MΩ·nm
Density: 3.68 to 4.50 g/cm³
Young's modulus: 300 to 350 GPa
Acoustic velocity: 5064 to 6048 m/s

### CrN Layer

Resistance value: 4000 Ω·nm
Density: 5. 9 g/cm³
Young's modulus: 300 to 400 GPa
Acoustic velocity: 4422 to 5106 m/s

### DLC Layer

Resistance value: 107 to 1014 Ω·cm
Density: 2.0 to 2.8 g/cm³
Young's modulus: 200 to 1000 GPa
Acoustic velocity: 4688 to 10483 m/s

### TiCN Layer

Resistance value: 200 Ω·nm
Density: 5.0 to 5.5 g/cm³
Young's modulus: 300 to 650 GPa
Acoustic velocity: 4580 to 7071 m/s

The Young's modulus of the CrAlN layer is 300 to 350 GPa, the Young's modulus of the CrN layer is 300 to 400 GPa, the Young's modulus of the DLC layer is 200 to 1000 GPa, and the Young's modulus of the TiCN layer is 300 to 650 GPa. Thus, the Young's modulus of the CrAlN layer, CrN layer, DLC layer, and TiCN layer are large, similar to the Young's modulus of the TiAlN layer. Therefore, in the second embodiment, by using the chromium aluminum nitride layer, the chromium nitride layer, the diamond-like carbon layer, or the titanium carbonitride layer as the first layer 31, the electric power durability can be improved and the TCF can be improved as in the first embodiment.

In the case where the first layer 31 is the chromium aluminum nitride layer, from the viewpoint of ensuring a high Young's modulus, the proportion of aluminum atoms is preferably 20 atomic % or more and 50 atomic % or less, more preferably 25 atomic % or more and 45 atomic % or less, and still more preferably 30 atomic % or more and 40 atomic % or less when the total of chromium atoms and aluminum atoms is 100 atomic %. From the viewpoint of ensuring the high Young's modulus, the proportion of nitrogen atoms is preferably 30 atomic % or more and 60 atomic % or less, more preferably 35 atomic % or more and 55 atomic % or less, and still more preferably 40 atomic % or more and 50 atomic % or less when the total of chromium atoms, aluminum atoms, and nitrogen atoms is 100 atomic %.

In the case where the first layer 31 is the chromium nitride layer, from the viewpoint of ensuring the high Young's modulus, the proportion of nitrogen atoms is preferably 30 atomic % or more and 60 atomic % or less, more preferably 35 atomic % or more and 55 atomic % or less, and further preferably 40 atomic % or more and 50 atomic % or less when the total of chromium atoms and nitrogen atoms is 100 atomic %.

In the case where the first layer 31 is the titanium carbonitride layer, from the viewpoint of ensuring the high Young's modulus, the proportion of titanium atoms is preferably 40 atomic % or more and 70 atomic % or less, more preferably 45 atomic % or more and 65 atomic % or less, and further preferably 50 atomic % or more and 60 atomic % or less when the total of titanium atoms, carbon atoms, and nitrogen atoms is 100 atomic %. From the viewpoint of ensuring the high Young's modulus, the proportion of carbon atoms to the total of carbon atoms and nitrogen atoms (carbon atoms/(carbon atoms+nitrogen atoms)) is preferably 50% or more and 70% or less, more preferably 54% or more and 66% or less, and still more preferably 58% or more and 62% or less.

### Third Embodiment

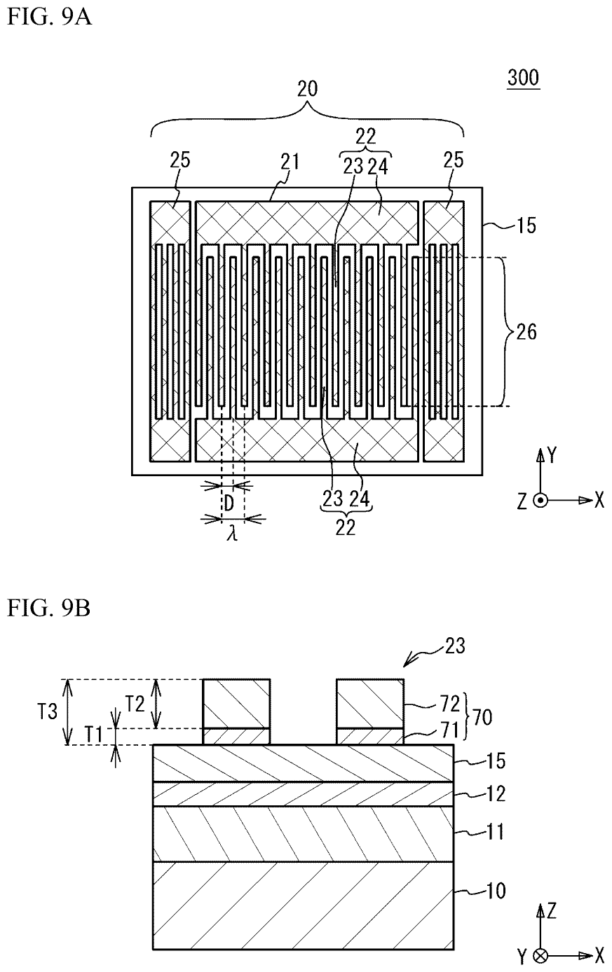

FIG. 9A is a plan view of an acoustic wave device 300 in accordance with a third embodiment, and FIG. 9B is a cross-sectional view of the electrode fingers 23 in the third embodiment.

As illustrated in FIGS. 9A and 9B, the piezoelectric layer 15 is provided on the substrate 10. The insulating layer 12 is provided between the substrate 10 and the piezoelectric layer 15. The insulating layer 11 is provided between the substrate 10 and the insulating layer 12. The acoustic wave resonator 20 is provided on the piezoelectric layer 15.

As illustrated in FIG. 9B, the IDT 21 including the electrode finger 23, and the reflector 25 are formed of a conductive film 70 provided on the piezoelectric layer 15. The conductive film 70 includes a first layer 71 provided on the piezoelectric layer 15 and a second layer 72 provided on the first layer 71. The thicknesses of the first layer 71 and the second layer 72 are denoted by T1 and T2, respectively. The thickness of the conductive film 70 is denoted by T3. In the third embodiment, “T3=T1+T2” is satisfied.

The first layer 71 is a layer formed of a conductive material, and is, for example, polycrystalline or amorphous. The electrical resistivity of the first layer 71 is greater than 1272 Ω·nm and equal to or less than 25038 Ω·nm. The thickness T1 of the first layer 71 varies depending on the band in which the acoustic wave devices 100 are used, but is, for example, 10 nm or more and 600 nm or less when used in the low band (less than 1 GHZ), 10 nm or more and 90 nm or less when used in the middle band (equal to or greater than 1 GHz and equal to or less than 7 GHz), and 5 nm or more and 60 nm or less when used in the high band (greater than 7 GHZ). The thickness T1 of the first layer 71 may be, for example, 5% or more and 50% or less of the thickness T3 of the electrode finger 23. The first layer 71 is, for example, a single-layer film of a titanium nitride (TiN) layer, a titanium aluminum alloy (TiAl) layer, a titanium aluminum alloy nitride (TiAlN) layer, or an aluminum copper alloy nitride (AlCuN) layer, or a stacked film thereof. The TiN layer may contain an intentional or unintentional impurity other than Ti and N. The TiAl layer may contain an intentional or unintentional impurity other than Ti and Al. The TiAlN layer may contain an intentional or unintentional impurity other than Ti, Al, and N. The AlCuN layer may contain an intentional or unintentional impurity other than Al, Cu, and N.

The second layer 72 has a lower electrical resistivity than the first layer 71, and is, for example, an aluminum (Al) layer or an aluminum alloy (Al alloy) layer, and is, for example, polycrystalline or amorphous. In the case where the second layer 72 is the Al alloy layer, the second layer 72 may contain at least one element of copper (Cu), magnesium (Mg), scandium (Sc), zirconium (Zr), titanium (Ti), neodymium (Nd), and silicon (Si), in addition to Al. In the case where the second layer 72 is the Al layer, the second layer 72 may include an intentional or unintentional impurity other than Al. In the case where the second layer 72 is the Al alloy layer, the second layer 72 may contain an intentional or unintentional impurity other than Al and the metal element constituting the Al alloy. The content of Al in the second layer 72 is, for example, 80 atomic % or more, and 90 atomic % or more. The thickness T2 of the second layer 72 may be greater than the thickness T1 of the first layer 71. The thickness T2 of the second layer 72 varies depending on the band in which the acoustic wave device 100 is used, and is, for example, 150 nm or more and 600 nm or less when used in the low band (less than 1 GHZ), 50 nm or more and 200 nm or less when used in the middle band (equal to or greater than 1 GHz and equal to or less than 7 GHZ), and 10 nm or more and 120 nm or less when used in the high band (greater than 7 GHZ). The thickness T2 of the second layer 72 may be, for example, 50% or more and 95% or less of the thickness T3 of the electrode finger 23. The other configurations of the third embodiment are the same as those of the first embodiment, and thus the description thereof will be omitted.

### [Manufacturing Method]

The acoustic wave device 300 in accordance with the third embodiment is manufactured by the following method. First, the insulating layer 11 and the insulating layer 12 are formed on the substrate 10 in this order from closest to the substrate 10. The insulating layer 11 and the insulating layer 12 are formed by, for example, a sputtering method, a chemical vapor deposition method (CVD method), or a vacuum evaporation method. Next, the piezoelectric layer 15 is bonded to the insulating layer 12 by using, for example, a surface activation method. Thereafter, the piezoelectric layer 15 is polished to a desired thickness by using, for example, a chemical mechanical polishing method (CMP method). Next, the first layer 71 and the second layer 72 are formed on the piezoelectric layer 15 in this order from closest to the piezoelectric layer 15 by, for example, the sputtering method, the CVD method, or the vacuum evaporation method. Thereafter, the first layer 71 and the second layer 72 are formed into desired shapes by the photolithography method and the etching method, thereby forming the IDT 21 and the reflector 25. As described above, the acoustic wave device 300 in accordance with the third embodiment is formed.

### Experiment 2

A plurality of samples were prepared by forming a titanium (Ti) film, a titanium aluminum alloy (TiAl) film, a titanium nitride (TiN) film, a titanium aluminum alloy nitride (TiAlN) film, and an aluminum copper alloy (AlCu) film on a silicon substrate, and the electrical resistivities of the Ti film, the TiAl film, the TiN film, the TiAlN film, and the AlCu film were measured. The thickness of each film was 200 nm, and the electric resistivities were measured using a four terminal method. Each film was formed by the following method.

### Formation of Ti Film

Film formation by sputtering using Ti target and argon (Ar) gas

### Formation of TiAl Film

Film formation by sputtering using TiAl alloy target and Ar gas
Composition ratio of TiAl target: Ti-32 wt % Al

### Formation of TiN Film

Film formation by sputtering using Ti target, Ar gas, and nitrogen gas (N₂)

### Formation of TiAlN Film

Film formation by sputtering using TiAl target, Ar gas, and N₂ gas
Composition ratio of TiAl target: Ti-32 wt % Al

### Formation of AlCu Film

Film formation by sputtering using AlCu alloy target and Ar gas
Composition ratio of AlCu target: Al-1 wt % Cu

Table 2 illustrates the measurement results of the electrical resistivities of the Ti film, the TiAl film, the TiN film, the TiAlN film, and the AlCu film. For reference, the values of the electrical resistivity described in the literature are also illustrated.

TABLE 2

Electrical resistivity [Ω · nm]

| | Measured value | Literature value |
|---|---|---|
| Ti film | 602 | 420 |
| TiAl film | 2079 | 550 |
| TiN film | 1272 | 20~300000 |
| TiAlN film | 25038 | 1000~125000 |
| AlCu film | 50 | 34~55 |

As illustrated in Table 2, the measured value of the Ti film was 602 Ω·nm, the measured value of the TiAl film was 2079 Ω·nm, the measured value of the TiN film was 1272 Ω·nm, the measured value of the TiAlN film was 25038 Ω·nm, and the measured value of the AlCu film was 50 Ω·nm. The measured values were somewhat different from the literature values.

### Experiment 3

A ladder-type filter using the acoustic wave resonator 20 in the third embodiment was manufactured, and the pass characteristics were measured. As the ladder-type filter, four samples E, F, G, and H were manufactured using different materials for the conductive film 70 forming the IDT 21 and the reflectors 25 of the acoustic wave resonator 20. The materials and the like used for the conductive film 70 are illustrated below. The first layer 71 and the second layer 72 in the samples E, F, G, and H were formed by the method described in the above Paragraph 0089.

### Substrate Configuration of Samples E, F, G, and H

Substrate 10: sapphire substrate
Insulating layer 11: aluminum oxide (Al₂O₃) layer having thickness of 6 μm
Insulating layer 12: silicon oxide (SiO₂) layer having thickness of 300 nm
Piezoelectric layer 15: 36° rotated Y-cut X-propagation lithium tantalate (LiTaO₃) layer with thickness of 450 nm

### Electrode Configuration of Sample E

First layer 71: titanium (Ti) layer having thickness T1 of 60 nm
Second layer 72: aluminum-copper alloy (AlCu) layer having thickness T2 of 90 nm

### Electrode Configuration of Sample F

First layer 71: titanium aluminum alloy (TiAl) layer having thickness T1 of 60 nm
Second layer 72: aluminum-copper alloy (AlCu) layer having thickness T2 of 90 nm

### Electrode Configuration of Sample G

First layer 71: titanium nitride (TiN) layer having thickness T1 of 60 nm
Second layer 72: aluminum-copper alloy (AlCu) layer having thickness T2 of 90 nm

### Electrode Configuration of Sample H

First layer 71: titanium aluminum alloy nitride (TiAlN) layer having thickness T1 of 60 nm
Second layer 72: aluminum-copper alloy (AlCu) layer having thickness T2 of 90 nm

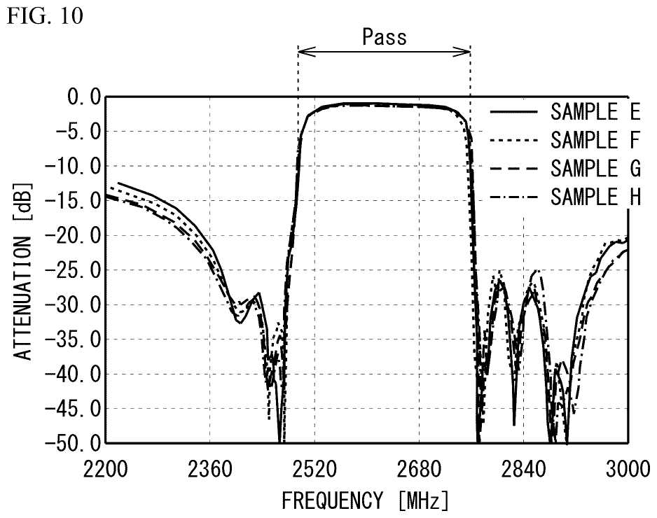

FIG. 10 is a diagram illustrating results of pass characteristics of the samples E, F, G, and H in Experiment 2. In FIG. 10, a horizontal axis represents frequency, and a vertical axis represents attenuation. The measurement result of the sample E is indicated by a solid line, the measurement result of the sample F is indicated by a dotted line, the measurement result of the sample G is indicated by a broken line, and the measurement result of the sample His indicated by a dashed-dotted line. In FIG. 10, the band characteristics are shifted so that the frequencies of the −5 dB coincide with each other in the attenuation on the low frequency side of a passband Pass. As illustrated in FIG. 10, the widths of the passbands Pass of all the samples E, F, G, and H were substantially the same. In the samples E, F, G, and H, the second layer 72 is the same as the AlCu layer, whereas the first layers 71 are formed of different materials. In the sample E, the first layer 71 is a Ti layer, and the electrical resistivity is 602 Ω·nm as illustrated in Table 1. In the sample F, the first layer 71 is a TiAl layer and the electrical resistivity is 2079 Ω·nm. In the sample G, the first layer 71 is a TiN layer and the electrical resistivity is 1272 Ω·nm. In the sample H, the first layer 71 is a TiAlN layer and the electrical resistivity is 25038 Ω·nm.

When the electrode fingers 23 having a large electric resistance are used in the IDT 21, the electromechanical coupling coefficient of the acoustic wave resonator 20 is reduced, and as a result, the width of the passband of the band pass filter is reduced. However, as illustrated in FIG. 10, the sample H using the first layer 71 including the TiAlN layer having an electrical resistivity of 25038 Ω·nm has substantially the same width of the passband Pass as the sample E using the first layer 71 including the Ti layer having an electrical resistivity of 602 Ω·nm. From this, it is understood that the electromechanical coupling coefficient is reduced when the electrode fingers 23 having the large electrical resistance is used, but the reduction in the electromechanical coupling coefficient is suppressed until the electrical resistivity of the first layer 71 reaches 25038 Ω·nm.

### Experiment 4

Samples I, J, and K were manufactured using aluminum copper nitride (AlCuN) layers formed under different film formation conditions as the first layer 71 in the acoustic wave resonator 20 in the third embodiment, and the electromechanical coupling coefficients were measured. The substrate configurations of the samples I, J, and K are the same as those of the samples E to H of Experiment 3. The electrode configurations of the samples I, J, and K are as follows.

### Electrode Configurations of Samples I, J, and K

First layer 71: Aluminum-copper-nitride (AlCuN) layer having thickness T1 of 60 nm
Second layer 72: aluminum-copper alloy (AlCu) layer having thickness T2 of 90 nm
Average pitch D: 1.5 μm

The film formation conditions of the first layer 71 in the samples I, J, and K are as follows. The film formation conditions of the second layer 72 are the same as the film formation conditions described in Paragraph 0089.

### Film Formation Conditions of First Layer 71 of Sample I

Film formation by sputtering using AlCu-alloy target, Ar gas, and N₂ gas
Composition ratio of AlCu target: Al-1 wt % Cu
Ar gas flow rate: 4 sccm, N₂ gas flow rate: 4 sccm

### Film Formation Conditions of First Layer 71 of Sample J

Film formation by sputtering using AlCu-alloy target, Ar gas, and N₂ gas
Composition ratio of AlCu target: Al-1 wt % Cu
Ar gas flow rate: 6 sccm, N₂ gas flow rate: 6 sccm

### Film Formation Conditions of First Layer 71 of Sample K

Film formation by sputtering using AlCu-alloy target, Ar gas, and N₂ gas
Composition ratio of AlCu target: Al-1 wt % Cu
Ar gas flow rate: 8 sccm, N₂ gas flow rate: 8 sccm

Here, first, AlCuN films were formed on silicon substrates under the film formation conditions illustrated in the above Samples I to K, and the results of measuring the electrical resistivities and the composition ratios are illustrated in Table 3. The thickness of the AlCuN film is the 200 nm. The electrical resistivities were measured by the four terminal method, and the composition ratios were measured by X-ray photoelectron spectroscopy (XPS).

TABLE 3

| | Ar/N₂ gas | Electrical | |
|---|---|---|---|
| | flow rate | resistivity | Composition ratio [%] |
| | [sccm] | [Ω · nm] | Al/Cu/N/O |
| AlCuN film | 4/4 | 684 | 67.6/0.8/30.3/1.3 |
| | 6/6 | 1587 | 59.4/0.6/38.7/1.3 |
| | 8/8 | 11350 | 54.1/0.3/44.2/1.4 |

As illustrated in Table 3, the electric resistivity of the AlCuN film formed by setting the gas flow rates of Ar and N₂ to 4 sccm was 684 Ω·nm. The electric resistivity when the gas flow rate was set to 6 sccm was 1587 Ω·nm. The electric resistivity when the gas flow rate was set to 8 sccm was 11350 Ω·nm. As the flow rate of the N₂ gas was increased, the ratio of N in the AlCuN film increased, and the ratios of Al and Cu in the AlCuN film decreased, so that the electric resistivity increased.

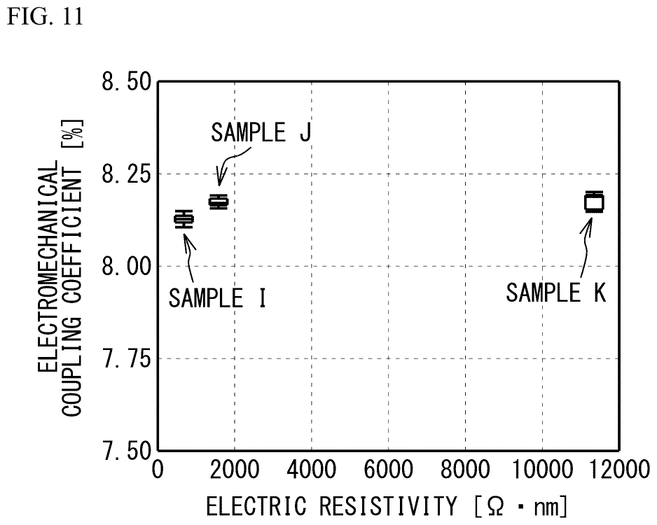

Next, the electromechanical coupling coefficients of the samples I, J, and K are illustrated. FIG. 11 is a diagram illustrating the results of the electromechanical coupling coefficients of the samples I, J, and K in Experiment 4. FIG. 11 is a box plot, where a horizontal axis represents electric resistivity of the first layer 71 and a vertical axis represents electromechanical coupling coefficient k2. As illustrated in FIG. 11, the electromechanical coupling coefficients k2 were substantially the same as each other in the range of the electric resistivity of the first layer 71 from 684 Ω·nm (sample I) to 11350 Ω·nm (sample K).

### Modifications

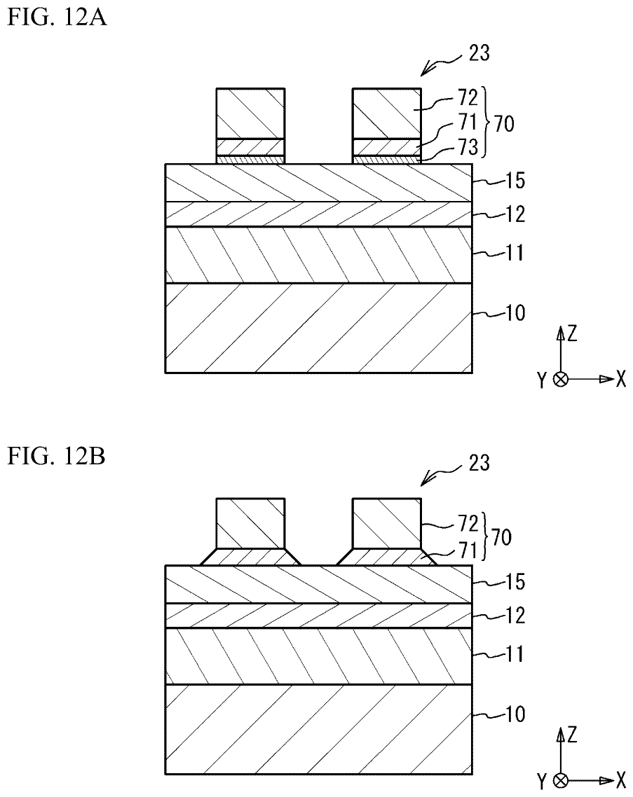

FIG. 12A is a cross-sectional view of the electrode fingers 23 in a first modification of the third embodiment. As illustrated in FIG. 12A, a buffer layer 73 may be provided between the piezoelectric layer 15 and the first layer 71. The buffer layer 73 is, for example, a titanium layer or a titanium nitride layer, and is provided to increase the orientation of aluminum of the second layer 72, for example. The thickness of the buffer layer 73 is, for example, from 2 nm to 10 nm. The other configurations of the first modification of the third embodiment are the same as those of the third embodiment, and thus the description thereof will be omitted.

FIG. 12B is a cross-sectional view of the electrode fingers 23 in a second modification of the third embodiment. As illustrated in FIG. 12B, the first layer 71 may have a tapered shape in which the width in the X direction increases from the second layer 72 toward the piezoelectric layer 15. The other configurations of the second modification of the third embodiment are the same as those of the third embodiment, and thus the description thereof will be omitted.

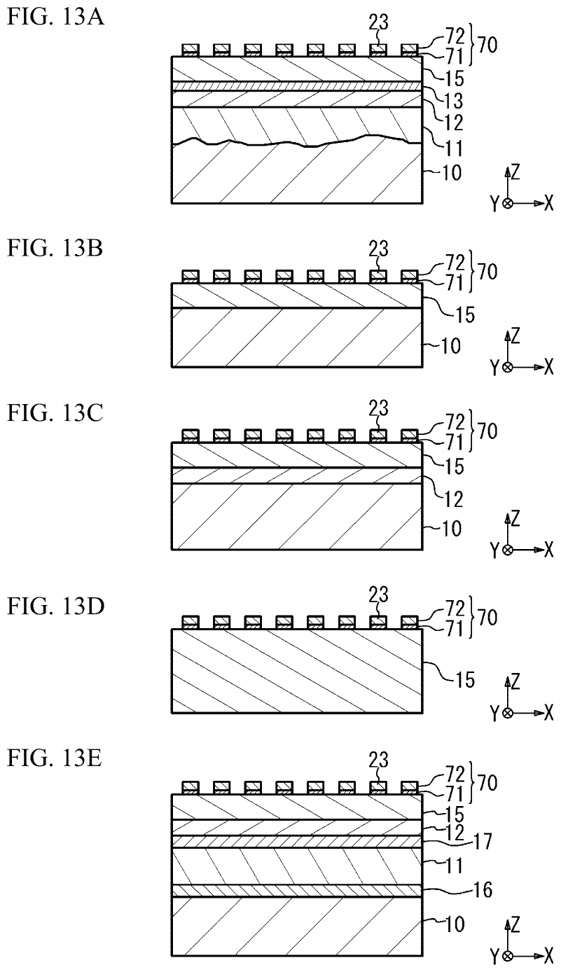

FIG. 13A is a cross-sectional view of an acoustic wave device in accordance with a third modification of the third embodiment. As illustrated in FIG. 13A, the insulating layer 13 may be provided between the insulating layer 12 and the piezoelectric layer 15. Although the interface between the substrate 10 and the insulating layer 11 is the mirror surface in the third embodiment, the interface between the substrate 10 and the insulating layer 11 may be the rough surface. The arithmetic average roughness Ra of the rough surface is, for example, larger than 10 nm and equal to or smaller than 100 nm, and the arithmetic average roughness Ra of the mirror surface is, for example, equal to or smaller than 10 nm and is about 1 nm. The other configurations of the third modification of the third embodiment are the same as those of the third embodiment, and thus the description thereof will be omitted.

FIG. 13B is a cross-sectional view of an acoustic wave device in accordance with a fourth modification of the third embodiment. As illustrated in FIG. 13B, the insulating layer 11 and the insulating layer 12 may not be provided between the substrate 10 and the piezoelectric layer 15, and the piezoelectric layer 15 may be provided on the upper surface of the substrate 10. The other configurations of the fourth modification of the third embodiment are the same as those of the third embodiment, and thus the description thereof will be omitted.

FIG. 13C is a cross-sectional view of an acoustic wave device in accordance with a fifth modification of the third embodiment. As illustrated in FIG. 13C, the insulating layer 11 may not be provided between the substrate 10 and the insulating layer 12, and the insulating layer 12 may be provided on the upper surface of the substrate 10. The interface between the substrate 10 and the insulating layer 12 may be the mirror surface or the rough surface. The other configurations of the fifth modification of the third embodiment are the same as those of the third embodiment, and thus the description thereof will be omitted.

FIG. 13D is a cross-sectional view of an acoustic wave device in accordance with a sixth modification of the third embodiment. As illustrated in FIG. 13D, the substrate 10, the insulating layer 11, and the insulating layer 12 may not be provided, and the piezoelectric layer 15 may be the piezoelectric substrate. The other configurations of the sixth modification of the third embodiment are the same as those of the third embodiment, and thus the description thereof will be omitted.

FIG. 13E is a cross-sectional view of an acoustic wave device in accordance with a seventh modification of the third embodiment. As illustrated in FIG. 13E, an insulating layer 16 may be provided between the substrate 10 and the insulating layer 11, and an insulating layer 17 may be provided between the insulating layer 11 and the insulating layer 12. The insulating layer 16 is, for example, an aluminum oxide layer, an aluminum nitride layer, or a silicon oxide layer. The insulating layer 17 is, for example, an aluminum nitride layer, a silicon nitride layer, a silicon carbide layer, a DLC (diamond carbon) layer, or a boron nitride layer. The other configurations of the seventh modification of the third embodiment are the same as those of the third embodiment, and thus the description thereof will be omitted.

In the third embodiment and the modifications thereof, the electrode finger 23 includes the first layer 71 having an electrical resistivity of more than 1272 Ω·nm and 25038 Ω·nm or less, and the second layer 72 provided on the first layer 71 and having an electrical resistivity less than that of the first layer 71. Although the electromechanical coupling coefficient k2 decreases as the electric resistance of the electrode fingers 23 increases, the decrease in the electromechanical coupling coefficient k2 can be suppressed when the electric resistivity of the first layer 71 is greater than 1272 Ω·nm and less than or equal to 25038 Ω·nm, as described with reference to FIGS. 10 and 11. Therefore, it is possible to widen the range of choices of the material used for the first layer 71 while suppressing a decrease in the electromechanical coupling coefficient k2.

In order to significantly suppress a decrease in the electromechanical coupling coefficient k2, the electric resistivity of the first layer 71 is preferably less than or equal to 11350 Ω·nm, more preferably less than or equal to 10000 Ω·nm, and still more preferably less than or equal to 8000 Ω·nm. The electrical resistivity of the first layer 71 may be 1500 Ω·nm or more, may be 2000 Ω·nm or more, or may be 3000 Ω·nm or more.

In the third embodiment and the modifications thereof, the thickness T1 of the first layer 71 is less than or equal to 50% of the thickness T3 of the electrode finger 23. By setting the first layer 71 having a high electric resistivity to be equal to or less than half of the electric resistance of the electrode finger 23, it is possible to suppress an increase in the electric resistance of the electrode finger 23 and to suppress a decrease in the electromechanical coupling coefficient k2. From the viewpoint of suppressing the decrease in the electromechanical coupling coefficient k2, the thickness T1 of the first layer 71 is preferably equal to or less than 40%, more preferably equal to or less than 35%, and still more preferably equal to or less than 30% of the thickness T3 of the electrode finger 23, based on the experimental results of FIGS. 10 and 11.

In the third embodiment and the modifications thereof, the second layer 72 is an Al layer or an Al alloy layer. This reduces the electric resistance of the electrode fingers 23, and thus suppresses the decrease in the electromechanical coupling coefficient k2. The second layer 72 may be a copper (Cu) layer or a copper (Cu) alloy layer in addition to the Al layer or the Al alloy layer. Even in this case, the electric resistance of the electrode fingers 23 can be reduced, and thus, the decrease in the electromechanical coupling coefficient k2 can be suppressed. In the case where the second layer 72 is the Cu layer, the second layer 72 may contain an intentional or unintentional impurity other than Cu. In the case where the second layer 72 is the Cu alloy layer, the second layer 72 may contain an intentional or unintentional impurity other than Cu and the metal element constituting the Cu alloy. The content of Cu in the second layer 72 is, for example, 80 atomic % or more, or 90 atomic % or more.

In the third embodiment and the modifications thereof, the thickness T1 of the first layer 71 is equal to or larger than 10 nm. If the thickness T1 of the first layer 71 is too small, even when the first layer 71 is provided to obtain a certain effect, the effect of providing the first layer 71 is difficult to obtain. However, when the thickness T1 is equal to or greater than 10 nm, the effect of providing the first layer 71 is easily obtained. For example, when the first layer 71 is provided to improve the adhesion between the electrode finger 23 and the piezoelectric layer 15 and/or to improve the electric power durability of the electrode finger 23, the effect of improving the adhesion and/or the electric power durability is obtained by setting the thickness T1 of the first layer 71 to be equal to or larger than 10 nm.

In the third embodiment and the modifications thereof, the first layer 71 includes a TiN layer, a TiAl layer, a TiAlN layer, or an AlCuN layer. TiN, TiAl, TiAlN, and AlCuN have a relatively large Young's modulus. Since the Young's modulus of the first layer 71 is large, the second layer 72 is less likely to be deformed even when the electrode finger 23 is excited. Therefore, the distortion generated in the second layer 72 is reduced and the electromigration is suppressed, so that the electric power durability is improved. In addition, the Young's modulus of TIN, TiAl, TiAlN, and AlCuN changes with temperature, and the temperature change in the Young's modulus of the Young's modulus of TIN, TiAl, TiAlN, and AlCuN is larger than that in the Young's modulus of the piezoelectric layer 15. Since the first layer 71 has the large Young's modulus, the first layer 71 is less likely to be deformed even when the Young's modulus of the first layer 71 and the second layer 72 changes with temperature. Therefore, the temperature coefficient of frequency (TCF) is improved. In addition, a material having the large Young's modulus has a high acoustic velocity. It is considered that the first layer 71 having the high acoustic velocity is provided as a base layer of the second layer 72, and thus a large amount of acoustic wave energy is distributed in the piezoelectric layer 15. Therefore, the TCF is improved also by this.

In the third embodiment and the modifications thereof, a protective film may be provided on the piezoelectric layer 15 to cover the electrode fingers 23. The thickness of the protective film may be smaller or larger than the thickness of the electrode finger 23. In the case where the thickness of the protective film is larger than the thickness of the electrode finger 23, the upper surface of the protective film may be subjected to a flattening process.

### Fourth Embodiment

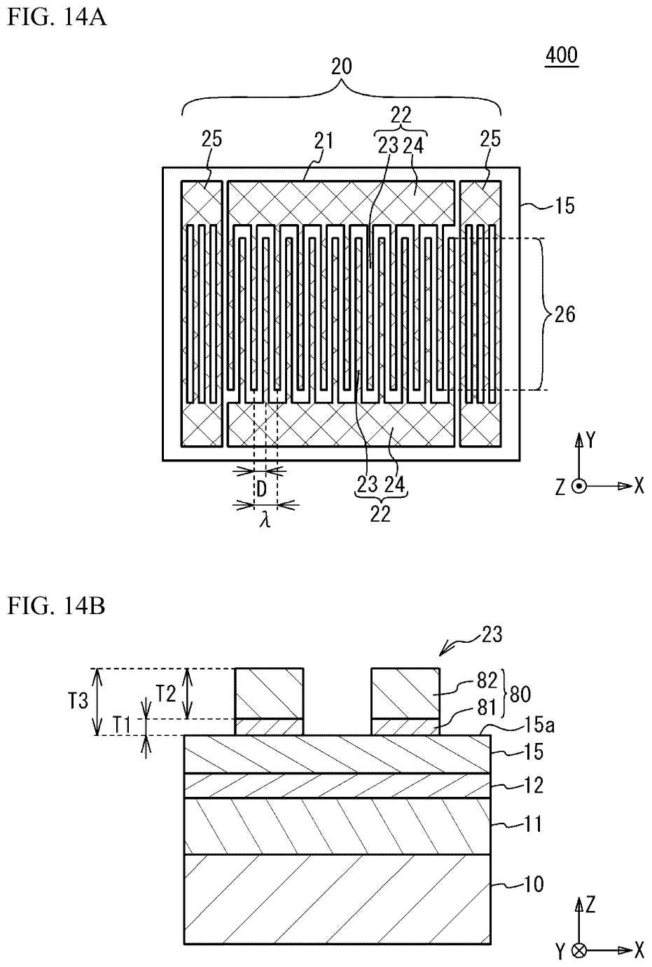

FIG. 14A is a plan view of an acoustic wave device 400 in accordance with a fourth embodiment, and FIG. 14B is a cross-sectional view of the electrode fingers 23 in the fourth embodiment.

As illustrated in FIGS. 14A and 14B, the piezoelectric layer 15 is provided on the substrate 10. The insulating layer 12 is provided between the substrate 10 and the piezoelectric layer 15. The insulating layer 11 is provided between the substrate 10 and the insulating layer 12. The acoustic wave resonator 20 is provided on the piezoelectric layer 15.

As illustrated in FIG. 14B, the IDT 21 including the electrode finger 23, and the reflector 25 are formed by a conductive film 80 provided on an upper surface 15a of the piezoelectric layer 15. The arithmetic average roughness Ra of the upper surface 15a is 0.60 nm or less. The arithmetic average roughness Ra is defined in JIS B 0601 and ISO 4287. The conductive film 80 includes a first layer 81 provided on the upper surface 15a of the piezoelectric layer 15, and a second layer 82 provided on the upper surface of the first layer 81. The thicknesses of the first layer 81 and the second layer 82 are denoted by T1 and T2, respectively. The thickness of the conductive film 80 is denoted by T3. “T3=T1+T2” is satisfied.

The first layer 81 is electrically conductive. The Young's modulus of the first layer 81 is larger than the Young's modulus of the second layer 82, and is preferably, for example, twice or more the Young's modulus of the second layer 82. The first layer 81 is, for example, a titanium (Ti) layer, a titanium nitride (TiN) layer, a titanium aluminum alloy (TiAl) layer, or a titanium aluminum nitride alloy (TiAlN) layer, and is, for example, polycrystalline. In the case of the Ti layer, the first layer 81 may contain an intentional or unintentional impurity other than Ti. In the case of the TiN layer, the first layer 81 may contain an intentional or unintentional impurity other than Ti and N. In the case of the TiAl layer, the first layer 81 may contain intentional or unintentional impurities other than Ti and Al. In the case of the TiAlN layer, the first layer 81 may contain an intentional or unintentional impurity other than Ti, Al, and N.

The thickness T1 of the first layer 81 varies depending on the band in which the acoustic wave devices 100 are used, and is, for example, 120 nm or more and 300 nm or less when used in the low band (less than 1 GHz), 30 nm or more and 90 nm or less when used in the middle band (equal to or greater than 1 GHz and equal to or less than 7 GHZ), and 5 nm or more and 60 nm or less than when used in the high band (greater than 7 GHZ). The thickness T1 of the first layer 81 may be, for example, 5% or more and 50% or less of the thickness T3 of the electrode finger 23.

The second layer 82 has a lower electrical resistivity than the first layer 81. The second layer 82 is an aluminum (Al) layer or an aluminum alloy (Al alloy) layer, and is, for example, polycrystalline. The second layer 82 has a crystal state in which the Al (111) orientation is dominant. The orientation can be obtained by, for example, measurement by X-ray diffraction, measurement with an electron microscope, or the like. In the case where the second layer 82 is the Al alloy layer, the second layer 82 includes at least one element of copper (Cu), magnesium (Mg), scandium (Sc), zirconium (Zr), titanium (Ti), neodymium (Nd), and silicon (Si), in addition to Al. In the case where the second layer 82 is the Al layer, the second layer 82 may include an intentional or unintentional impurity other than Al. In the case where the second layer 82 is the Al alloy layer, the second layer 82 may contain an intentional or unintentional impurity other than Al and the metal element constituting the Al alloy. The content of Al in the second layer 82 is, for example, 80 atomic % or more, or 90 atomic % or more. The thickness T2 of the second layer 82 is equal to or larger than the thickness T1 of the first layer 81. The thickness T2 of the second layer 82 varies depending on the band in which the acoustic wave device 100 is used, and is, for example, 150 nm or more and 350 nm or less when used in the low band (less than 1 GHZ), 100 nm or more and 200 nm or less when used in the middle band (equal to or greater than 1 GHz and equal to or less than 7 GHZ), and 80 nm or more and 120 nm or less when used in the high band (greater than 7 GHZ). For example, the thickness T2 of the second layer 82 is 50% or more and 95% or less of the thickness T3 of the electrode finger 23. The other configurations of the fourth embodiment are the same as those of the first embodiment, and thus the description thereof will be omitted.

### [Manufacturing Method]

The acoustic wave device 400 in accordance with the fourth embodiment is manufactured by the following method. First, the insulating layer 11 and the insulating layer 12 are formed on the substrate 10 in this order from closest to the substrate 10. The insulating layer 11 and the insulating layer 12 are formed by, for example, a sputtering method, a chemical vapor deposition method (CVD method), or a vacuum evaporation method. Next, the piezoelectric layer 15 is bonded to the insulating layer 12 by using, for example, a surface activation method. Thereafter, the piezoelectric layer 15 is polished to a desired thickness by using, for example, a chemical mechanical polishing method (CMP method). By setting the polishing conditions to appropriate conditions, the arithmetic average roughness Ra of the upper surface 15a of the piezoelectric layer 15 can be set to 0.60 nm or less. The arithmetic average roughness Ra can be made to be 0.60 mm or less by cleaning the upper surface 15a with an organic solution instead of or in addition to the polishing. Next, the first layer 81 and the second layer 82 are formed on the piezoelectric layer 15 in this order from closest to the piezoelectric layer 15 by using, for example, the sputtering method, the CVD method, or the vacuum evaporation method. Thereafter, the first layer 81 and the second layer 82 are formed into desired shapes by the photolithography method and the etching method, thereby forming the IDT 21 and the reflector 25. As described above, the acoustic wave device 400 in accordance with the fourth embodiment is formed.

### Experiment 5

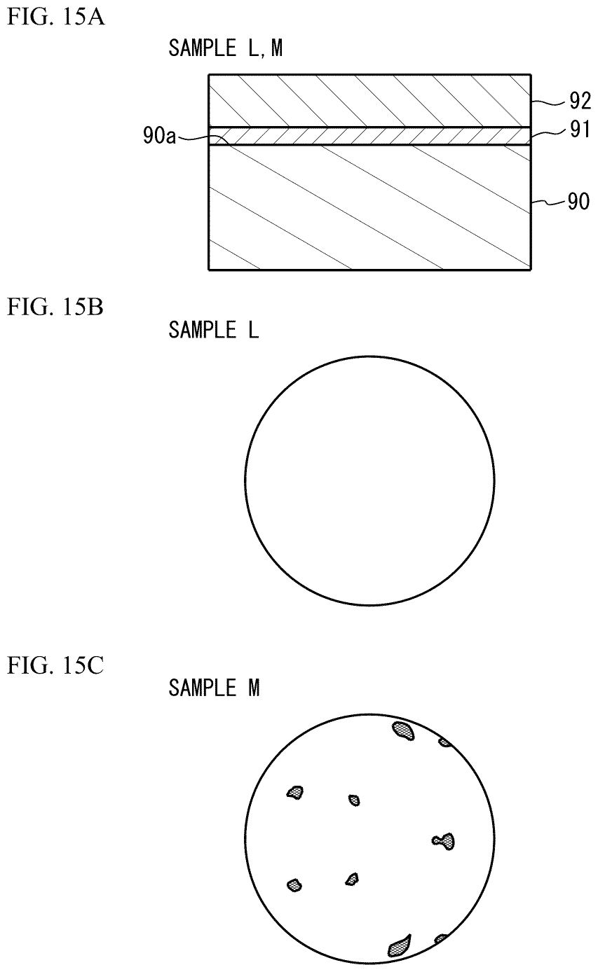

FIG. 15 a is a cross-sectional view of a sample L and a sample M used in the experiment. As illustrated in FIG. 15A, both the sample L and the sample M have a configuration in which a titanium nitride film 91 (hereinafter referred to as a TiN film 91) and an aluminum-copper alloy film 92 (hereinafter referred to as an AlCu film 92) in which copper is added to aluminum by 1.0 atomic % are stacked on a single crystal lithium tantalate substrate 90 (hereinafter referred to as an LT substrate 90) in this order from closest to the LT substrate 90. The thickness of the TiN film 91 is 40 nm, and the thickness of the AlCu film 92 is 100 nm.

In the sample L, an upper surface 90a of the LT substrate 90 was subjected to reverse sputtering (etch-back) treatment before the TiN film 91 was formed. The upper surface 90a becomes uneven by the reverse sputtering. The arithmetic average roughness Ra of the upper surface 90a after the reverse sputtering was measured to be 0.62 nm. The TiN film 91 was formed on the upper surface 90a having the arithmetic average roughness Ra of 0.62 nm after the reverse sputtering.

In the sample M, the upper surface 90a of the LT substrate 90 was polished by the CMP method before the TiN film 91 was formed. The arithmetic average roughness Ra of the upper surface 90a after the polishing treatment was 0.23 nm. The TiN film 91 was formed on the upper surface 90a having the arithmetic average roughness Ra of 0.23 nm after the polishing treatment.

In the samples L and M, the TiN film 91 was formed by sputtering using the Ti target, argon (Ar) gas, and nitrogen gas (N₂). The AlCu film 92 was formed by sputtering using the AlCu alloy target and Ar gas.

Pole figure measurement was performed on the Al (111) orientation of the AlCu film 92 in the sample L and the sample M. FIGS. 15B and 15C are schematic views illustrating the results of pole measurement of the Al (111) orientation of the AlCu film 92 in the sample L and the sample M. As illustrated in FIG. 15B, in the sample L, the change in diffraction intensity depending on the orientation was small, and thus it was confirmed that the AlCu film 92 did not have the Al (111) orientation but had a random orientation. In the sample L, the TiN film 91 is formed on the upper surface 90a of the LT substrate 90 having the arithmetic average roughness Ra of 0.62 nm. As described above, the TiN film 91 is formed on the upper surface 90a having a large roughness, and thus it is considered that the TiN film 91 is not in the (111) orientation but in the random orientation. Since the AlCu film 92 is considered to be formed on the TIN film 91 having the random orientation, the AlCu film 92 is also considered to have the random orientation following the TiN film 91.

As illustrated in FIG. 15C, in the sample M, the diffraction intensity was observed only in a specific direction, and it was confirmed that the AlCu film 92 had the Al (111) orientation and had six fold rotational symmetry. In the sample M, the TiN film 91 is formed on the upper surface 90a of the LT substrate 90 having the arithmetic average roughness Ra of 0.23 nm. As described above, the TiN film 91 is formed on the upper surface 90a having a small roughness, and thus is considered to be in a crystalline state in which the (111) orientation is dominant. Since the AlCu film 92 is considered to be formed on the TiN film 91 having the (111) orientation, the AlCu film 92 is considered to have the Al (111) orientation.

Next, acoustic wave resonators were manufactured using Sample L and Sample M, and the electric power durability test was performed. The electric power durability test employed a step stress accelerated life test (SSALT) in which the applied power was increased stepwise. As a result of the power durability test, the loss of the acoustic wave resonator manufactured using the sample L was significantly deteriorated when the applied power reached 33.2 dBm. In the acoustic wave resonator manufactured using the sample M, the loss was significantly deteriorated when the applied power reached 35.5 dBm. As described above, the acoustic wave resonator using the sample M had a higher power durability than the acoustic wave resonator using the sample L.

When the appearance of the acoustic wave resonator after the electric power durability test was observed, the occurrence of electromigration was suppressed in the acoustic wave resonator using the sample M as compared with the acoustic wave resonator using the sample L. This suggests that the acoustic wave resonator using the sample M has improved power durability because the occurrence of electromigration is suppressed. The AlCu film 92 of the sample L has the random orientation, whereas the AlCu film 92 of the sample M has the Al (111) orientation. This indicates that the use of the Al layer or the Al alloy layer having the Al (111) orientation for the electrode fingers of the acoustic wave device can suppress the occurrence of electromigration and improve the power durability.

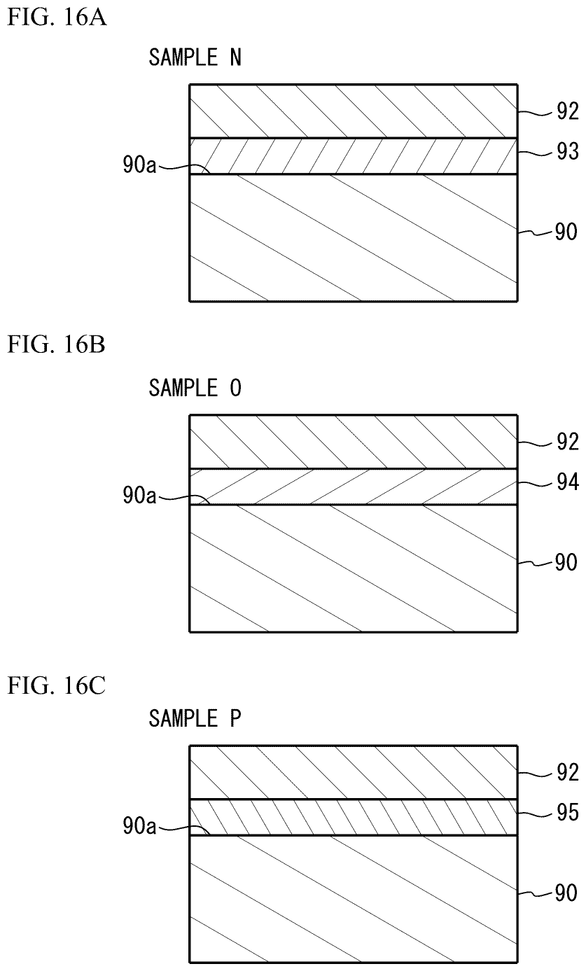

Next, pole measurement was performed on the Al (111) orientation of the AlCu film 92 in samples N, O, and P using films formed of other materials instead of the TiN film 91. FIGS. 16A to 16C are cross-sectional views of the samples N to P used in the experiment. As illustrated in FIG. 16A, in the sample N, a titanium aluminum nitride alloy film 93 (hereinafter referred to as a TiAlN film 93) was formed on the upper surface 90a of the LT substrate 90 having an arithmetic average roughness Ra of about 0.23 nm. The AlCu film 92 was formed on the TiAlN film 93. The thickness of the TiAlN film 93 is 40 nm, and the thickness of the AlCu film 92 is 100 nm. The TiAlN film 93 was formed by sputtering using the TiAl-alloy target, Ar gas, and N₂ gas. The AlCu film 92 was formed by the method described in Paragraph 0123.

As illustrated in FIG. 16B, in the sample O, a titanium film 94 (hereinafter referred to as a Ti film 94) was formed on the upper surface 90a of the LT substrate 90 having an arithmetic average roughness Ra of about 0.23 nm. The AlCu film 92 was formed on the Ti film 94. The thickness of the Ti film 94 is 40 nm, and the thickness of the AlCu film 92 is 100 nm. The Ti film 94 was formed by sputtering using the Ti target and Ar gas. The AlCu film 92 was formed by the method described in Paragraph 0123.

As illustrated in FIG. 16C, in the sample P, a titanium aluminum alloy film 95 (hereinafter referred to as a TiAl film 95) was formed on the upper surface 90a of the LT substrate 90 having the arithmetic average roughness Ra of about 0.23 nm. The AlCu film 92 was formed on the TiAl film 95. The thickness of the TiAl film 95 is 40 nm, and the thickness of the AlCu film 92 is 100 nm. The TiAl film 95 was formed by sputtering using the TiAl alloy target and Ar gas. The AlCu film 92 was formed by the method described in Paragraph 0123.

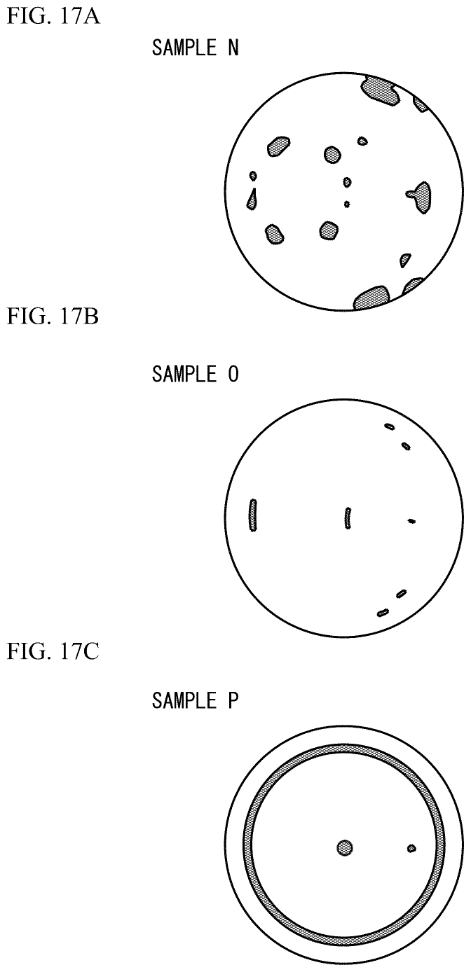

FIGS. 17A to 17C are schematic diagrams illustrating results of pole measurement of the Al (111) orientation of the AlCu film 92 in the samples N to P. As illustrated in FIG. 17A, it was confirmed that the AlCu film 92 of the sample N had the Al (111) orientation and the six fold rotational symmetry. It is considered that the TiAlN film 93 is formed on the upper surface 90a of the LT substrate 90 having the small roughness, and thus the TiAlN film 93 is in a crystalline state in which the (111) orientation is dominant. Therefore, it is considered that the AlCu film 92 has the Al (111) orientation. As illustrated in FIG. 17B, it was confirmed that the AlCu film 92 of the sample O had the Al (111) orientation and the three fold rotational symmetry. It is considered that the Ti film 94 is formed on the upper surface 90a of the LT substrate 90 having the small roughness, and thus the Ti film 94 is in a crystalline state in which the (002) orientation is dominant. Therefore, it is considered that the AlCu film 92 has the Al (111) orientation. As illustrated in FIG. 17C, in the sample P, the diffraction intensity was observed to have a ring-shaped distribution, and it was confirmed that the AlCu film 92 had the Al (111) orientation although it was uniaxially oriented. It is considered that the TiAl film 95 is formed on the upper surface 90a of the LT substrate 90 having the small roughness, and thus the TiAl film 95 is in a crystalline state in which the (111) orientation is dominant. Therefore, it is considered that the AlCu film 92 has the Al (111) orientation.

As described above, it was confirmed that even when a film made of a material other than the TiN film was provided, the AlCu film 92 had the Al (111) orientation by being formed on the upper surface 90a of the LT substrate 90 having the small roughness.

Acoustic wave resonators were manufactured using the samples N to P, and the electric power durability test was performed. The electric power durability test was performed by a step stress test method as in the case of the sample L and the sample M. As a result of the power durability test, the applied power when the loss was significantly deteriorated was 35.8 dBm for the acoustic wave resonator using the sample N, 34.0 dBm for the acoustic wave resonator using the sample O, and 34.0 Bm for the acoustic wave resonator using the sample P. The applied power when the loss significantly deteriorated in the acoustic wave resonator using sample L was 33.2 dBm, and thus the electric power durability of the samples N to P was improved as compared with the sample L. This is considered to be because the AlCu films 92 of the samples N to P have the Al (111) orientation.

In the fourth embodiment, as illustrated in FIG. 14B, the first layer 81 is provided on the upper surface 15a of the piezoelectric layer 15 having the arithmetic average roughness Ra of 0.60 nm or less, and the second layer 82, which is the Al layer or the Al-alloy layer, is provided on the first layer 81. Thereby, in view of the experimental results recited above, the second layer 82 has the Al (111) orientation. Therefore, the power durability can be improved.

Next, Table 4 illustrates the relationship between the lattice constant of each layer in the samples M to P and the applied power when the insertion loss is deteriorated. The lattice constant was measured using an X-ray diffraction (XRD) method.

TABLE 4

| | | | | Applied power |
|---|---|---|---|---|
| | Lattice constant [Å] | | | [dBm] |
| SAMPLE M | Ti film 91 | AlCu film 92 | Difference | 35.5 |
| | 4.24 | 4.05 | 0.19 | |
| SAMPLE N | TiAlN film 93 | AlCu film 92 | Difference | 35.8 |
| | 4.02 | 4.05 | −0.03 | |
| SAMPLE O | Ti film 94 | AlCu film 92 | Difference | 34.0 |
| | 4.68 | 4.05 | 0.63 | |
| SAMPLE P | TiAl film 95 | AlCu film 92 | Difference | 34.0 |
| | 4.29 | 4.05 | 0.24 | |

As illustrated in Table 4, in the sample M, the difference in lattice constant between the TiN film 91 and the AlCu film 92 was 0.19 Å. In the sample N, the difference in lattice constant between the TiAlN film 93 and the AlCu film 92 was −0.03 Å. In the sample O, the difference in lattice constant between the Ti film 94 and the AlCu film 92 was 0.63 Å. In the sample P, the difference in lattice constant between the TiAl film 95 and the AlCu film 92 was 0.24 Å. The applied power when the loss is deteriorated is 35.5 dBm and 35.8 dBm in the sample M and the sample N, respectively, and is larger than 34.0 dBm in the sample O and the sample P. From this, it is considered that when the lattice constant of the base layer (TiN film 91 or the like) is close to the lattice constant of the upper layer (AlCu film 92), the upper layer has a good Al (111) orientation, and the electric power durability is improved.

Therefore, in the fourth embodiment, the electric power durability is improved as the difference in the lattice constant between the first layer 81 and the second layer 82 is smaller. From the viewpoint of improving the electric power durability, the difference between the lattice constant of the first layer 81 and the lattice constant of the second layer 82 is preferably ±0.15 Å or less, more preferably ±0.10 Å or less, and still more preferably ±0.05 Å or less.

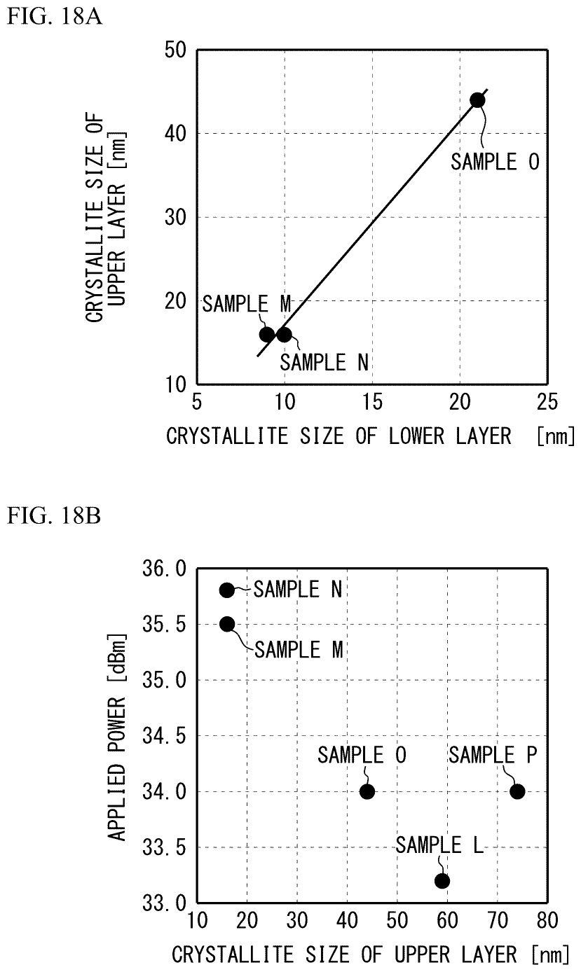

Next, the crystallite sizes of the TiN film 91, the TiAlN film 93, the Ti film 94, the TiAl film 95, and the AlCu film 92 in the samples L to P were measured. The crystallite size was measured using the X-ray diffraction (XRD) method. FIGS. 18A and 18B are diagrams illustrating measurement results of crystallite sizes in the samples L to P. In FIGS. 18A and 18B, the TiN film 91, the TiAlN film 93, the Ti film 94, and the TiAl film 95 are referred to as lower layers, and the AlCu film 92 is referred to as an upper layer. FIG. 18A illustrates the results of the crystallite size of the upper layer with respect to the crystallite size of the lower layer. The crystallite sizes of the lower layers (the TiN film 91, the TiAlN film 93, and the Ti film 94) in the samples M to O were able to be measured, but the crystallite sizes of the lower layers (the TiN film 91 and the TiAl film 95) in the samples L and P were not able to be measured. FIG. 18B is a diagram illustrating the applied power when the loss is significantly deteriorated in the electric power durability test with respect to the crystallite size of the upper layer.

As illustrated in FIG. 18A, the results were that the crystallite size of the upper layer depended on the crystallite size of the lower layer. That is, the results were that the crystallite size of the upper layer was small when the crystallite size of the lower layer was small, and the crystallite size of the upper layer was large when the crystallite size of the lower layer was large. When the crystallite size of the lower layer was equal to or less than 10 nm, the crystallite size of the upper layer was equal to or less than 20 nm.

As illustrated in FIG. 18B, when the crystallite size of the upper layer was 20 nm or less, the applied power when the loss was significantly deteriorated in the electric power durability test was 35.5 dBm or more, and the electric power durability was improved. This is considered to be because the smaller the crystallite size, the less electromigration occurred.

This indicates that the electric power durability can be improved by setting the crystallite size of the lower layer to be equal to or less than 10 nm. Therefore, in the fourth embodiment, from the viewpoint of improving the electric power durability, the crystallite size of the first layer 81 is preferably equal to or less than 10 nm, more preferably equal to or less than 9 nm, and still more preferably equal to or less than 8 nm. The crystallite size of the second layer 82 is preferably equal to or less than 20 nm, more preferably equal to or less than 18 nm, and still more preferably equal to or less than 16 nm.

### Modifications

The fourth embodiment may have the same configuration as the third to seventh modifications of the third embodiment illustrated in FIGS. 13A to 13E.

In the fourth embodiment and the modifications thereof, the piezoelectric layer 15 has the upper surface 15a (front surface) having the arithmetic average roughness Ra of 0.60 nm or less. The electrode finger 23 includes the first layer 81 provided on the upper surface 15a, and the second layer 82 provided on the first layer 81, having the thickness T1 equal to or larger than the thickness T2 of the first layer 81, and being an aluminum layer or an aluminum alloy layer having an electric resistivity smaller than that of the first layer 81. The second layer 82 has the Al (111) orientation by providing the first layer 81 and the second layer 82 on the upper surface 15a having the arithmetic average roughness Ra of 0.60 nm or less. Therefore, the electric power durability can be improved. From the viewpoint of improving the electric power durability, the arithmetic average roughness Ra of the upper surface 15a is preferably equal to or less than 0.40 nm, more preferably equal to or less than 0.30 nm, still more preferably equal to or less than 0.25 nm, and yet still more preferably equal to or less than 0.23 nm.

In the fourth embodiment and the modifications thereof, the difference between the lattice constant of the first layer 81 and the lattice constant of the second layer 82 is +0.15 Å or less. This can improve the electric power durability as illustrated in Table 1.

In the fourth embodiment and the modifications thereof, the crystallite size of the first layer 81 is equal to or less than 10 nm. This can improve the electric power durability as illustrated in FIGS. 5A and 5B.

In the fourth embodiment and the modifications thereof, the Young's modulus of the first layer 81 is greater than the Young's modulus of the second layer 82. Since the first layer 81 having a large Young's modulus is provided as a base film of the second layer 82, the second layer 82 is less likely to be deformed even when the electrode finger 23 is excited. Thereby, the strain that occurs in the second layer 82 is reduced and electromigration is suppressed, and therefore the electric power durability can be improved. The Young's modules of the first layer 81 is preferably equal to or higher than 270 GPa, and more preferably equal to or higher than 310 GPa. The density of the first layer 81 may be 5.2 g/cm³ or less, or 4.5 g/cm³ or less.

In the fourth embodiment and the modifications thereof, the first layer 81 is the TiAlN layer. This can improve the electric power durability as illustrated in Table 1. In addition, the Young's modulus of the material constituting the electrode fingers 23 changes with temperature, and the temperature change in the Young's modulus of the Young's modulus of the material constituting the electrode fingers 23 is larger than that in the Young's modulus of the piezoelectric layer 15. Since TiAlN has a large Young's modulus, the first layer 81 is less likely to be deformed even when the Young's modulus of the first layer 81 and the second layer 82 changes with temperature. Therefore, it is considered that the TCF is improved. In addition, since TiAlN has a large Young's modulus, the acoustic velocity is high. It is considered that when the first layer 81 having a high acoustic velocity is provided as the base film of the second layer 82, a large amount of acoustic wave energy is distributed in the piezoelectric layer 15. This is also considered to improve the TCF.

### Fifth Embodiment

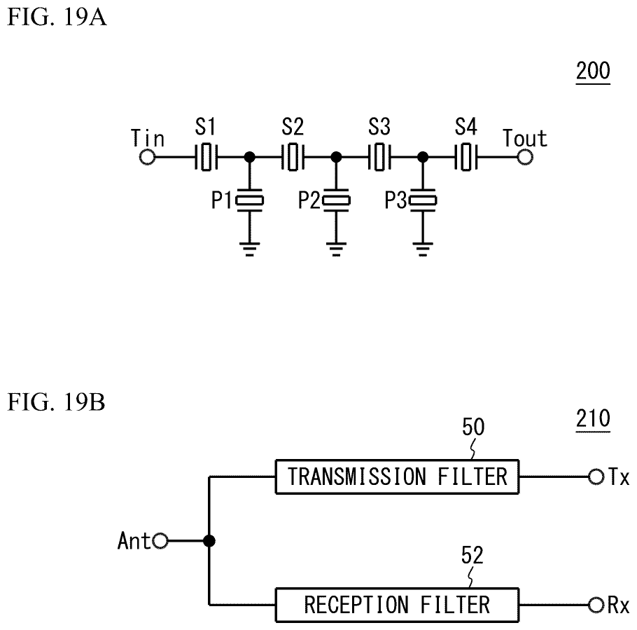

FIG. 19A is a circuit diagram of a filter 200 in accordance with a fifth embodiment. As illustrated in FIG. 19A, one or more series resonators S1 to S4 are connected in series between an input terminal Tin and an output terminal Tout. One or more parallel resonators P1 to P3 are connected in parallel between the input terminal Tin and the output terminal Tout. The acoustic wave devices according to the first to the fourth embodiments and the modifications thereof can be used for at least one of the series resonators S1 to S4 and the parallel resonators P1 to P3. The number of series resonators and parallel resonators, and the like can be set as appropriate. Although the ladder-type filter is illustrated as an example of the filter, the filter may be a multi-mode filter.

FIG. 19B is a circuit diagram of a duplexer 210 in accordance with a modification of the fifth embodiment. As illustrated in FIG. 19B, a transmission filter 50 is connected between a common terminal Ant and a transmission terminal Tx. A reception filter 52 is connected between the common terminal Ant and a reception terminal Rx. The transmission filter 50 transmits signals in a transmission band to the common terminal Ant as transmission signals among high-frequency signals input from the transmit terminal Tx, and suppresses signals having frequencies other than frequencies in the transmission band. The reception filter 52 transmits signals in a reception band to the reception terminal Rx as reception signals among the high-frequency signals input from the common terminal Ant, and suppresses signals having frequencies other than frequencies in the reception band. At least one of the transmission filter 50 and the reception filter 52 may be the filter of the second embodiment. Although a duplexer is illustrated as an example of a multiplexer, a triplexer or a quadplexer may be used.

Although the embodiments of the present disclosure have been described in detail above, the present disclosure is not limited to the specific embodiments, and various change, substitutions, and alterations could be made hereto without departing from the spirit and scope of the disclosure.

What is claimed is:

1. An acoustic wave device comprising:
a piezoelectric layer; and
a pair of interdigital electrodes including electrode fingers, each of the electrode fingers including a first layer provided on the piezoelectric layer and having an electrical resistivity of more than 1272 Ω·nm and 25038 Ω·nm or less, and a second layer provided on the first layer and having an electrical resistivity smaller than that of the first layer.

2. The acoustic wave device according to claim 1,
wherein a thickness of the first layer is equal to or less than 50% of the thickness of each of the electrode fingers.

3. The acoustic wave device according to claim 1,
wherein the second layer includes an aluminum layer, an aluminum alloy layer, a copper layer, or a copper alloy layer.

4. The acoustic wave device according to claim 1,
wherein a thickness of the first layer is equal to or larger than 10 nm.

5. The acoustic wave device according to claim 1,
wherein the first layer includes a titanium nitride layer, a titanium aluminum layer, a titanium aluminum nitride layer, or an aluminum copper nitride layer.

6. The acoustic wave device according to claim 1,
wherein the first layer has an electrical resistivity of more than 1272 Ω·nm and 11350 Ω·nm or less.

7. An acoustic wave device comprising:
a piezoelectric layer; and
a pair of interdigital electrodes including electrode fingers, each of the electrode fingers having a first layer provided on the piezoelectric layer and being a titanium aluminum nitride layer, a chromium aluminum nitride layer, a chromium nitride layer, a diamond-like carbon layer, or a titanium carbonitride layer, and a second layer provided on the first layer and being a metal layer formed of a metal having an electrical resistivity smaller than that of the first layer.

8. The acoustic wave device according to claim 7,
wherein the first layer is a titanium aluminum nitride layer, and a proportion of aluminum atoms is 20 atomic % or more and 50 atomic % or less when a total of titanium atoms and aluminum atoms is 100 atomic %.

9. The acoustic wave device according to claim 7,
wherein the first layer is a titanium aluminum nitride layer, and a proportion of nitrogen atoms is 10 atomic % or more when a total of titanium atoms, aluminum atoms, and nitrogen atoms is 100 atomic %.

10. The acoustic wave device according to claim 7,
wherein the second layer is an aluminum layer, an aluminum alloy layer, a copper layer, or a copper alloy layer.

11. The acoustic wave device according to claim 7,
wherein the thickness of the first layer is 5% or more and 60% or less of the thickness of each of the electrode fingers.

12. The acoustic wave device according to claim 7,
wherein each of the electrode fingers includes a third layer thinner than the first layer and the second layer between the first layer and the second layer,
the second layer is an aluminum layer, an aluminum alloy layer, a copper layer, or a copper alloy layer, and
the third layer is a titanium layer or a titanium nitride layer.

13. An acoustic wave device comprising:
a piezoelectric layer having a surface with an arithmetic average roughness Ra of 0.60 nm or less, and
a pair of interdigital electrodes including electrode fingers, each of the electrode fingers including a first layer provided on the piezoelectric layer and a second layer provided on the first layer, the second layer having a thickness equal to or greater than a thickness of the first layer and being an aluminum layer or an aluminum alloy layer having an electric resistivity smaller than that of the first layer.

14. The acoustic wave device according to claim 13,
wherein the arithmetic average roughness Ra of the surface is less than or equal to 0.25 nm.

15. The acoustic wave device according to claim 13,
wherein a difference between a lattice constant of the first layer and a lattice constant of the second layer is ±0.15 Å or less.

16. The acoustic wave device according to claim 13,
wherein the first layer has a crystallite size of 10 nm or less.

17. The acoustic wave device according to claim 13,
wherein a Young's modulus of the first layer is larger than a Young's modulus of the second layer.

18. The acoustic wave device according to claim 13,
wherein the first layer is a titanium aluminum nitride layer.

19. A filter comprising the acoustic wave device according to claim 1.

20. A multiplexer comprising a filter according to claim 19.
